(19) United States
(12) Patent Application Publication
(10) Pub. No.: US 2013/0105775 A1
(43) Pub. Date: May 2, 2013

(54) DISPLAY APPARATUS

(71) Applicant: CANON KABUSHIKI KAISHA, Tokyo (JP)

(72) Inventor: Itaru Takaya, Chiba-shi (JP)

(73) Assignee: CANON KABUSHIKI KAISHA, Tokyo (JP)

(21) Appl. No.: 13/663,773

(22) Filed: Oct. 30, 2012

(30) Foreign Application Priority Data
Oct. 31, 2011 (JP) 2011-238944
Sep. 21, 2012 (JP) 2012-207713

(51) Int. Cl. H01L 51/50

(52) U.S. Cl. 257/40; 257/E51.019; 257/E51.022

(57) ABSTRACT

A display apparatus includes red, green and blue organic EL elements that include a first and a second charge transport layer, each having the same thickness and common to all the organic EL elements. The red organic EL element includes a thickness adjustment layer between a red luminescent layer and the first charge transport layer, and has an emission position at the interface between the red luminescent layer and the thickness adjustment layer. The green organic EL element includes a green luminescent layer containing an assistant dopant whose content has been controlled so that the emission position lies in the green luminescent layer. The blue organic EL element has an emission position at the interface between the blue luminescent layer and the first charge transport layer or the second charge transport layer.

### BACKGROUND OF THE INVENTION

1. Field of the Invention

The present invention relates to a display apparatus that includes organic electroluminescent (organic EL) elements of three colors red, green and blue and displays full color images.

2. Description of the Related Art

In order to enhance the luminous efficiency of a display apparatus including red (R), green (G) and blue (B) organic EL elements, a technique has been known in which the charge transport layers of the organic EL elements are formed to different thicknesses according to the emission color of the element. In this technique, the luminous efficiency is enhanced by setting, for each color, the optical distance between the emission position and the reflection plane to an interference condition at which light having a wavelength of the corresponding color can be intensified.

In Japanese Patent Laid-Open No. 2000-323277, charge transport layers of at least red and green organic EL elements are formed in a pattern corresponding to the shape of the pixels by vacuum deposition using a metal mask so that the charge transport layers of red, green and blue organic EL elements have different thicknesses according to the emission colors.

On the other hand, with the increase in the definition of multi-color display apparatuses, in recent years, the pixel size of each color has been decreased, and high definition metal masks have been required for applying different materials each in a pattern corresponding to the pixels. Accordingly, the cost for manufacturing and maintaining the metal masks accounts for a large part of the manufacturing cost of the display apparatus.

### SUMMARY OF THE INVENTION

According to an aspect of the present invention, a display apparatus has a luminous efficiency enhanced by setting, for each emission color, the optical distance between the emission position and the reflection plane to an interference condition at which light of the corresponding color can be intensified. According to another aspect of the present invention, a method is provided for manufacturing the display apparatus with a reduced number of metal masks.

According to another aspect of the present invention, a display apparatus is provided which includes a red organic EL element that emits red light, a green organic EL element that emits green light, and a blue organic EL element that emits blue light. The red organic EL element includes a first electrode including a metal layer having a reflection plane, a first charge transport layer in contact with the first electrode, a red luminescent layer, a second charge transport layer, a second electrode in contact with the second charge transport layer, including a metal layer having a reflection plane, and a thickness adjustment layer between the first charge transport layer and the red luminescent layer or between the red luminescent layer and the second charge transport layer. The green organic EL element includes a first electrode including a metal layer having a reflection plane, a first charge transport layer in contact with the first electrode, a green luminescent layer in contact with the first charge transport layer, containing a host material, a luminescent dopant, and an assistant dopant, a second charge transport layer in contact with the green luminescent layer, and a second electrode in contact with the second charge transport layer, including a metal layer having a reflection plane. The blue organic EL element includes a first electrode including a metal layer having a reflection plane, a first charge transport layer in contact with the first electrode, a blue luminescent layer in contact with the first charge transport layer, a second charge transport layer in contact with the blue luminescent layer, and a second electrode in contact with the second charge transport layer, including a metal layer having a reflection plane. The first charge transport layer and second charge transport layer of each organic EL element are common to all the organic EL elements and each have a constant thickness. Each respective organic EL element has a first optical distance L₁ between the emission position of the luminescent layer and the reflection plane of the first electrode and a second optical distance L₂ between the emission position of the luminescent layer and the reflection plane of the second electrode, and the first optical distance L₁ and the second optical distance L₂ satisfy the following relationships:

(λ/16)×(−1−(4φ₁/π)≦L₁(λ/16)×(1−(4φ₁/π)); and

(λ/16)×(−1−(4φ₂/π)≦L₂(λ/16)×(1−(4φ₂/π),

wherein λ represents the emission wavelength of the respective organic EL element, φ₁ represents phase shift of light reflecting from the first electrode of the respective organic EL element, and φ₂ represents phase shift of light reflecting from the second electrode of the respective organic EL element.

The emission position of the blue luminescent layer may lie at the interface between the blue luminescent layer and the second charge transport layer of the blue organic EL element. The first optical distance of the blue organic EL element has been set by controlling the thicknesses of the first charge transport layer and the luminescent layer, and the second optical distance of the blue organic EL element has been set by controlling the thickness of the second charge transport layer. The first and second optical distances of the green organic EL element may have been set by controlling the thicknesses of the first charge transport layer, the green luminescent layer and the second charge transport layer, and the assistant dopant content in the green luminescent layer. The thickness adjustment layer may be disposed between the red luminescent layer and the first charge transport layer of the red organic EL element. The first optical distance of the red organic EL element has been set by controlling the thicknesses of the first charge transport layer and the thickness adjustment layer, and the second optical distance has been set by controlling the thicknesses of the second charge transport layer and the red luminescent layer.

The red luminescent layer may contain a host material, a luminescent dopant and an assistant dopant, and the thickness adjustment layer is made of the same material as the assistant dopant of the red luminescent layer.

The green organic EL element may satisfy relationship (I):

LUMO_{Gh}<LUMO_{Ga}<LUMO_{Ge}<HOMO_{Ga}<HOMO_{Gh}<HOMO_{Ge} (I)

LUMO_{Gh}, LUMO_{Ge} and LUMO_{Ga} represent the absolute values of the energy levels of lowest unoccupied molecular orbitals of the host material, luminescent dopant and assistant dopant of the green luminescent layer, respectively, and HOMO_{Gh}, HOMO_{Ge} and HOMO_{Ga} represent the absolute values of the energy levels of highest occupied molecular orbitals of the host material, luminescent dopant and assistant dopant of the green luminescent layer, respectively.

The first optical distance L₁ and second optical distance L₂ of each organic EL element may satisfy the following relationships:

3λ/16≦L₁≦5λ/16; and

3λ/16≦L₂≦5λ/16.

According to another aspect of the present invention, only the red, green, and blue luminescent layers and the thickness adjustment layer of the red organic EL element are formed through metal masks, and the number of metal masks can therefore be reduced relative to the known process. Consequently, a display apparatus having a high luminous efficiency can be manufactured at a low cost.

Further features of the present invention will become apparent from the following description of exemplary embodiments with reference to the attached drawings.

### BRIEF DESCRIPTION OF THE DRAWINGS

FIG. 1 is a schematic perspective view of a display apparatus according to an embodiment of the present invention.

FIGS. 2A and 2B are fragmentary schematic sectional views of display apparatuses according to embodiments of the present invention.

FIGS. 3A and 3B are fragmentary schematic sectional views of display apparatuses according to embodiments of the present invention.

FIG. 4 is an energy band diagram of the green luminescent layer of a display apparatus according to an embodiment of the present invention.

### DESCRIPTION OF THE EMBODIMENTS

### Fundamental Structure of Display Apparatus

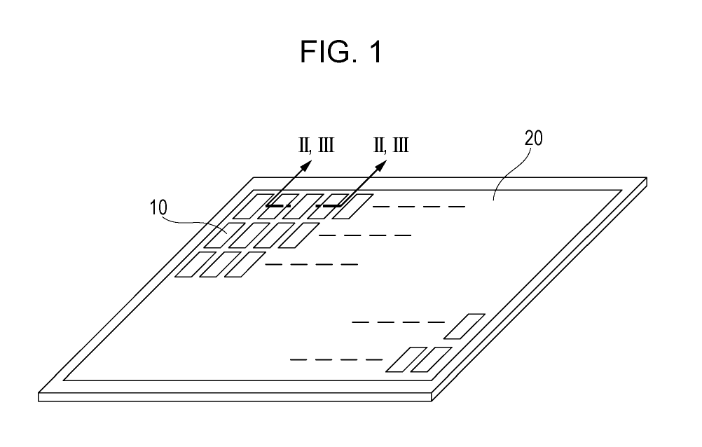

FIG. 1 is a schematic perspective view of a display apparatus according to an embodiment of the present invention. The display apparatus includes a plurality of pixels 10, each including an organic EL element. The pixels 10 are arranged in a matrix manner to define a display region 20. The term “pixel” refers to a region corresponding to the light-emitting region of any one of the organic EL elements. In the display apparatus of the present embodiment, each of the pixels 10 has an organic EL element that emits a single color. Each organic EL element emits any one of red, green and blue colors. A red pixel, a green pixel and a blue pixel constitute a pixel unit, and a plurality of pixel units are arranged in the display region 20. The pixel unit is a minimum unit capable of emitting desired color light by mixing the colors of the pixels.

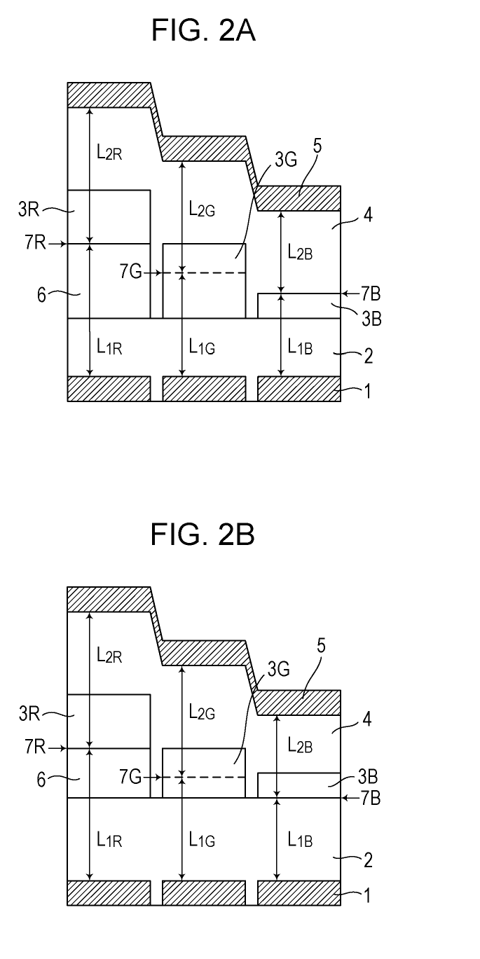

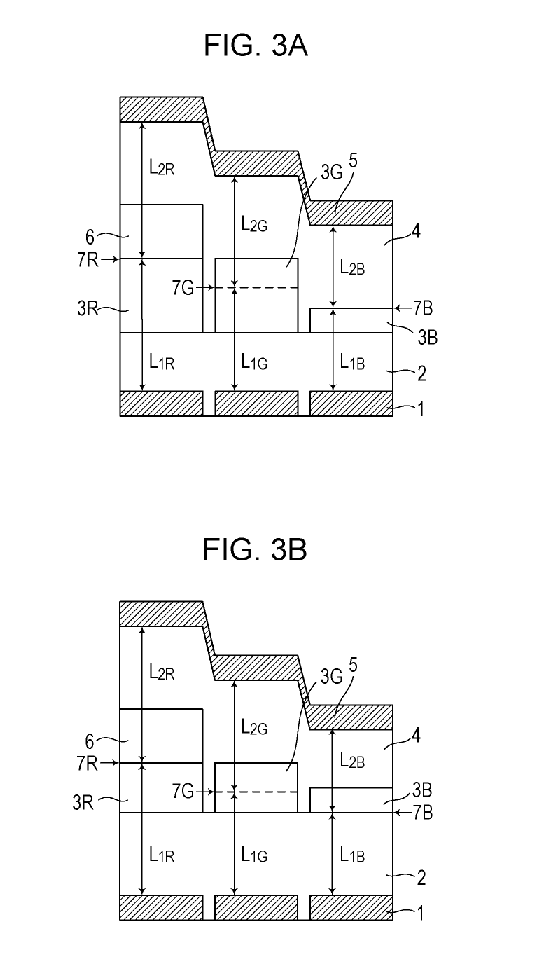

FIGS. 2A, 2B, 3A and 3B are each a fragmentary schematic sectional view taken along line II,III-II,III in FIG. 1. FIGS. 2A to 3B show four cases in which emission positions are different among the luminescent layers, and the structure shown in FIG. 2A is the most suitable for an embodiment.

Each pixel 10 has an organic EL element that includes a first electrode 1, a first charge transport layer 2, a luminescent layer, a second charge transport layer 4, and a second electrode 5 in that order on a substrate (not shown). Reference numerals 3R, 3G and 3B in FIGS. 2A and 2B designate a red luminescent layer, a green luminescent layer and a blue luminescent layer, respectively, and the positions indicated by arrows 7R, 7G and 7B are respective emission positions. The red organic EL element further includes a thickness adjustment layer 6 between the luminescent layer 3R and the first charge transport layer 2 or the second charge transport layer 4.

In any embodiment, the first charge transport layer 2 and the second charge transport layer 4 are common to all the organic EL elements. Therefore, the first and second charge transport layers 2 and 4 can be formed without using a metal mask having a pattern corresponding to the pixels.

### Emission Position and Element Structure

The emission position of each luminescent layer and the element structure will now be described with reference to FIGS. 2A, 2B, 3A and 3B.

### Blue Organic EL Element

The blue organic EL element that emits blue light includes a blue luminescent layer 3B. The blue luminescent layers 3B are formed by vapor deposition through a metal mask having a pattern corresponding to the pixels, and each of the blue luminescent layers 3B is disposed in contact with the first charge transport layer 2 and the second charge transport layer 4.

The emission position of the blue luminescent layer 3B is indicated by arrow 7B in FIGS. 2A to 3B. FIGS. 2B and 3B show cases in which the emission position 7B lies at the interface between the luminescent layer 3B and the first charge transport layer 2, and FIGS. 2A and 3A show cases in which the emission position 7B lies at the interface between the luminescent layer 3B and the second charge transport layer 4. In an embodiment, the emission position 7B of blue light may lie within the blue luminescent layer 3B, but this case is not shown.

The optical distance between the emission position 7B and the reflection plane of the first electrode 2, which is hereinafter referred to as the first optical distance L_{1B}, and the optical distance between the emission position 7B and the reflection plane of the second electrode 5, which is hereinafter referred to as the second optical distance L_{2B}, are each set so as to be one-fourth of the emission wavelength λ_{B}, of the blue luminescent layer 3B. The “optical distance” of a portion refers to the sum of the products of the refractive index and thickness of each layer disposed in the range of the physical distance of the portion. When the emission position 7B lies at the interface between the luminescent layer 3B and the first charge transport layer 2, as shown in FIGS. 2B and 3B, the first optical distance L_{1B} is set so as to be one-fourth of the blue emission wavelength λ_{B}, by adjusting the thickness of the first charge transport layer 2. The second optical distance L_{2B} is set so as to be one-fourth of the blue emission wavelength λ_{B} by adjusting the thicknesses of the luminescent layer 3B and the second charge transport layer 4. When the emission position 7B lies at the interface between the luminescent layer 3B and the second charge transport layer 4, as shown in FIGS. 2A and 3A, the first optical distance L_{1B}, is set so as to be one-fourth of the blue emission wavelength λ_{B}, by adjusting the thicknesses of the first charge transport layer 2 and the luminescent layer 3B. The second optical distance L_{2B} is set so as to be one-fourth of the blue emission wavelength λ_{B}, by adjusting the thickness of the second charge transport layer 4. When the emission position 7B lies inside the luminescent layer 3B, the first optical distance L_{1B}, from the emission position in the luminescent layer 3B to the reflection plane of the first electrode 1, is set so as to be one-fourth of the blue emission wavelength λ_{B} by adjusting the emission position and the thickness of the luminescent layer 3B in addition to the adjustment of the thickness of the first charge transport layer 2. Similarly, the second optical distance L_{2B}, from the emission position in the luminescent layer 3B to the reflection plane of the second electrode 5, is set so as to be one-fourth of the blue emission wavelength λ_{B}, by adjusting the thickness of the luminescent layer 3B and the emission position in addition to the adjustment of the thickness of the second charge transport layer 4.

In the formation of the blue organic EL elements, accordingly, a metal mask having a pattern corresponding to the pixels is used only for forming the blue luminescent layers 3B so that the first optical distance L_{1B}, and the second optical distance L_{2B} can be one-fourth of the blue emission wavelength λ_{B}.

### Green Organic EL Element

The green organic EL element that emits green light includes a green luminescent layer 3G. The green luminescent layers 3G are formed by vapor deposition through a metal mask having a pattern corresponding to the pixels. The green luminescent layer 3G contains a host material, a luminescent dopant and an assistant dopant, and is disposed in contact with the first charge transport layer 2 and the second charge transport layer 4. The emission position is set so as to be inside the luminescent layer 3G by controlling the assistant dopant content. The emission position of the green luminescent layer 3G is indicated by arrow 7G in FIGS. 2A to 3B.

As with the blue organic EL element, the first optical distance L_{2G} of the green organic EL element between the emission position 7G and the reflection plane of the first electrode 1 and the second optical distance L_{2G} between the emission position 7G and the reflection plane of the second electrode 5 are each set so as to be one-fourth of the emission wavelength λ_{G} of the green luminescent layer 3G.

The first optical distance L_{1G} from the emission position 7G in the green luminescent layer 3G to the reflection plane of the first electrode 1 is set so as to be one-fourth of the green emission wavelength λ_{G} by adjusting the emission position 7G and the thickness of the green luminescent layer 3G in addition to the adjustment of the thickness of the first charge transport layer 2, which has already been done in the process for forming the blue organic EL element. Similarly, the second optical distance L_{2G} from the emission position 7G in the green luminescent layer 3G to the reflection plane of the second electrode 5 is set so as to be one-fourth of the green emission wavelength λ_{G} by adjusting the thickness of the green luminescent layer 3G and the emission position 7G in addition to the adjustment of the thickness of the second charge transport layer 4, which has already been done in the process for forming the blue organic EL element.

In the formation of the green organic EL elements, accordingly, a metal mask having a pattern corresponding to the pixels is used only for forming the green luminescent layer 3G so that the first optical distance L_{1G} and the second optical distance L_{2G} can be one-fourth of the green emission wavelength λ_{G}.

### Red Organic EL Element

The red organic EL element that emits red light includes a thickness adjustment layer 6 between the red luminescent layer 3R and the first charge transport layer 2 or between the red luminescent layer 3R and the second charge transport layer 4. The emission position of the red luminescent layer 3R is indicated by arrow 7R in FIGS. 2A to 3B, and the red emission position 7R lies at the interface between the red luminescent layer 3R and the thickness adjustment layer 6. FIGS. 2A and 2B show cases in which the thickness adjustment layer 6 is disposed between the luminescent layer 3R and the first charge transport layer 2, and FIGS. 3A and 3B show cases in which the thickness adjustment layer 6 is disposed between the luminescent layer 3R and the second charge transport layer 4.

As with the blue and green organic EL elements, the first optical distance L_{1R} of the red organic EL element between the emission position 7R and the reflection plane of the first electrode 1 and the second optical distance L_{2R} between the emission position 7R and the reflection plane of the second electrode 5 are each set so as to be one-fourth of the emission wavelength λ_{R} of the red luminescent layer 3R.

When the emission position 7R lies at the boundary of the luminescent layer 3R on the first charge transport layer 2 side, the thickness adjustment layer 6 is disposed between the first charge transport layer 2 and the luminescent layer 3R, as shown in FIGS. 2A and 2B. The first optical distance L_{1R} of the red organic EL element is set so as to be one-fourth of the red emission wavelength λ_{R} by adjusting the thickness of the thickness adjustment layer 6 in addition to the adjustment of the thickness of the first charge transport layer 2, which has already been done in the process for forming the blue organic EL element. The second optical distance L_{2R} is set so as to be one-fourth of the red emission wavelength λ_{R} by adjusting the thickness of the luminescent layer 3R in addition to the adjustment of the thickness of the second charge transport layer 4, which has already been done in the process for forming the blue organic EL element. When the emission position 7R lies at the boundary of the luminescent layer 3R on the second charge transport layer 4 side, the thickness adjustment layer 6 is disposed between the luminescent layer 3R and the second charge transport layer 4, as shown in FIGS. 3A and 3B. In this instance, the first optical distance L_{2R} is set so as to be one-fourth of the red emission wavelength λ_{R} by adjusting the thickness of the luminescent layer 3R in addition to the adjustment of the thickness of the first charge transport layer 2, which has already been done in the process for forming the blue organic EL element. The second optical distance L_{2R} is set so as to be one-fourth of the red emission wavelength λ_{R} by adjusting the thicknesses of the thickness adjustment layer 6 in addition to the adjustment of the thickness of the second charge transport layer 4, which has already been done in the process for forming the blue organic EL element.

In the formation of the red organic EL elements, accordingly, a metal mask having a pattern corresponding to the pixels is used for forming the red luminescent layer 3R and the thickness adjustment layer 6 so that the first optical distance L_{1R} and the second optical distance L_{2R} can be one-fourth of the red emission wavelength λ_{R}.

As described above, the first and second optical distances L₁ and L₂ for each color can be set at one-fourth of the emission wavelength through a simple process in which metal masks are used in only four steps for forming the red, green and blue luminescent layers 3R, 3G and 3B and the thickness adjustment layer 6 of the red organic EL element. Thus, the number of times the metal masks are used can be reduced.

As described above, FIGS. 2A to 3B show four cases in which emission positions are different among the luminescent layers, and the structure shown in FIG. 2A is the most suitable for an embodiment. In the structure shown in FIG. 2A, the emission position 7R of the red luminescent layer 3R lies at the boundary of the red luminescent layer 3R on the first charge transport layer 2 side, and the emission position 7B of the blue luminescent layer 3B lies at the boundary of the blue luminescent layer 3B on the second charge transport layer 4 side. This is advantageous because the luminescent layers 3R and 3B each can be formed of a material having a high emission efficiency. The materials of the luminescent layers will be described later.

### First Optical Distance L₁ and Second Optical Distance L₂

Emission wavelengths λ_{R}, λ_{G} and λ_{E}, represent the wavelengths of red light, green light and blue light, respectively, and more specifically, each represent the peak wavelength in the spectrum of light emitted from the organic EL element, but not the peak wavelength in the emission spectrum of the luminescent material.

When the optical distance between an emission position and a reflection plane is set for each color to an interference condition at which light of a corresponding color can be intensified, as in an embodiment of the present invention, the optical distance L is expressed, allowing for the phase shift φ at the reflection plane, by the following equation (A):

L=(λ/4)×(2m−(φ/π)) (A)

where m represents an integer of 0 or more.

Since the first and second optical distances L₁ and L₂ are each one-fourth of the emission wavelength, m is 0, in any embodiment of the present invention. When m is 0, the effect of interference is the largest. When m is 1 or more, the differences in optical distance L among colors are increased. Accordingly, the thickness adjustment layer is provided for both red light and green light, or the green luminescent layer is formed to a very large thickness, consequently requiring a very high voltage. In the embodiment of the present invention, the thickness adjustment layer is used only in the red organic EL element, and m is therefore 0. When the phase shift is about −π, the first and second optical distances L₁ and L₂ are each one-fourth of the emission wavelength λ. In practice, however, the optical distances are set from Equation (A), allowing for the phase shift φ. In addition, Equation (A) may not fully apply to the optical distance due to the variation in deposition of an organic compound layer. However, as long as the deviation in optical distance from Equation (A) is about one-sixteenth of the emission wavelength, an effect of interference can be produced. Therefore, the first and second optical distances L₁ and L₂ can be set so as to satisfy the following relationship (B):

(λ/16)×(−1−(4φ/π))≦L≦(λ/16)×(1−(4φ/π)) (B)

Hence, when the phase shift of light reflecting from the reflection plane of the first electrode and the phase shift of light reflecting from the reflection plane of the second electrode are represented by φ₁ and φ₂, respectively, the first and second optical distances L₁ and L₂ in each organic EL element satisfy the following relationships:

(λ/16)×(−1−(4φ₁/π)≦L₁≦(λ/16)×(1−(4φ₁/π)); and

(λ/16)×(−1−(4φ₂/π)≦L₂≦(λ/16)×(1−(4φ₂/π)).

More specifically, the blue organic EL element satisfies the following relationships (C):

(λ_{B}/16)×(−1−(4φ_{1B}/π))≦L_{1B}≦(λ_{B}/16)×(1−(4φ_{1B}/π)); and

(λ_{B}/16)×(−1−(4φ_{2B}/π))≦L_{2B}≦(λ_{B}/16)×(1−(4φ_{2B}/π)) (C)

In the relationships, φ_{1B} represents the phase shift of light reflecting from the reflection plane of the first electrode of the blue organic EL element, and φ_{2B} represents the phase shift of light reflecting from the reflection plane of the second electrode of the blue organic EL element.

In addition, since φ_{1B} and φ_{2B} are each −π, the blue organic EL element satisfies the following relationships (C′):

3λ_{B}/16≦L_{1B}≦5λ_{B}/16; and

3λ_{B}/16≦L_{2B}≦5λ_{B}/16 (C′)

The green organic EL element satisfies the following relationships (D):

(λ_{G}/16)×(−1−(4φ_{1G}/π))≦L_{1G}≦(λ_{G}/16)×(1−(4φ_{1G}/π)); and

(λ_{G}/16)×(−1−(4φ_{2G}/π))≦L_{2G}≦(λ_{G}/16)×(1−(4φ_{2G}/π)) (D)

In the relationships, φ_{1G} represents the phase shift of light reflecting from the reflection plane of the first electrode of the green organic EL element, and φ_{2G} represents the phase shift of light reflecting from the reflection plane of the second electrode of the green organic EL element.

In addition, since φ_{1G} and φ_{2G} are each −π, the green organic EL element satisfies the following relationships (D′):

3λ_{G}/16≦L_{1G}≦5λ_{G}/16; and

3λ_{G}/16≦L_{2G}≦5λ_{G}/16 (D′)

The red organic EL element satisfies the following relationships (E):

(λ_{R}/16)×(−1−(4φ_{1R}/π))≦L_{1R}≦(λ_{R}/16)×(1−(4φ_{1R}/π)); and

(λ_{R}/16)×(−1−(4φ_{2R}/π))≦L_{2R}≦(λ_{R}/16)×(1−(4φ_{2R}/π)) (E)

In the relationships, φ_{1R} represents the phase shift of light reflecting from the reflection plane of the first electrode of the red organic EL element, and φ_{2R} represents the phase shift of light reflecting from the reflection plane of the second electrode of the red organic EL element.

In addition, since φ_{1G} and φ_{2G} are each −π, the red organic EL element satisfies the following relationships (E′):

3λ_{G}/16≦L_{1R}≦5λ_{R}/16; and

3λ_{G}/16≦L_{2R}≦5λ_{G}/16 (E′)

Therefore, in each organic EL element, the first optical distance L₁ between the emission position of the luminescent layer and the reflection plane of the first electrode and the second optical distance L₂ between the emission position and the reflection plane of the second electrode can satisfy the following relationships (F):

3λ/16≦L₁≦5λ/16; and

3λ/16≦L₂≦5λ/16 (F)

The phase shift φ at a reflection plane can be calculated with the refractive index n and absorption coefficient k of the material of the reflection plane.

The fact that an emission position (of the red or blue organic EL element) lies at the interface of two layers implies that the center of a light-emitting region lies inside the luminescent layer 0 to 5 nm away from the interfaces. The fact that the emission position (of the green organic EL element) lies within the luminescent layer suggests that the center of the light-emitting region lies inside the luminescent layer more than 5 nm away from an interface.

### Materials Used in Display Apparatus

An exemplary embodiment will now be described with reference to mainly the structure shown in FIG. 2A. In the following embodiment, the first electrode 1 disposed on a substrate acts as an anode, and the second electrode 5 acts as a cathode. The display apparatus is of top emission type that emits light from the side of the second electrode 5, opposite to the substrate. However, the anode and the cathode may be reversed, or the display apparatus may be of bottom emission type that emits light from the substrate side. The materials below will be described by way of example, and other materials may be used.

### First Electrode

The first electrodes 1 shown in FIG. 2A are formed on a substrate (not shown) in a pattern corresponding to the pixels, and each have a reflection plane defined by a metal layer. A transparent electroconductive material may be deposited on the metal layer.

The metal can be selected from among Al, Ag, Mo, W, Cr, Au, Sn, Si, Cu, Ti, Pt, Pd, Ni and so forth. These metals may be used in combination as an alloy or a multilayer film. The transparent electroconductive material may be an electroconductive metal oxide such as indium tin oxide (ITO) or indium zinc oxide. If a transparent electroconductive material is deposited on the metal reflection plane so that the transparent layer is disposed on the first charge transport layer 2 side, the optical thickness of the transparent layer is part of the first optical distance L₁ from the emission position to the reflection plane of the first electrode 1.

### First Charge Transport Layer

The first charge transport layer 2 is formed on the first electrode 1 in common to the organic EL elements. The first charge transport layer 2 can be formed by, for example, vapor deposition, coating or transfer. When the first electrode 1 is an anode, the first charge transport layer 2 is a hole transport layer. The hole transport layer can be made of arylamine or other known hole transport materials. The hole transport layer may have a multilayer structure formed by depositing a hole injection material, a hole transport material and an electron blocking material. In an embodiment, the hole transport layer may include a hole injection layer and an electron blocking layer. Exemplary materials of the hole transport layer are shown below:

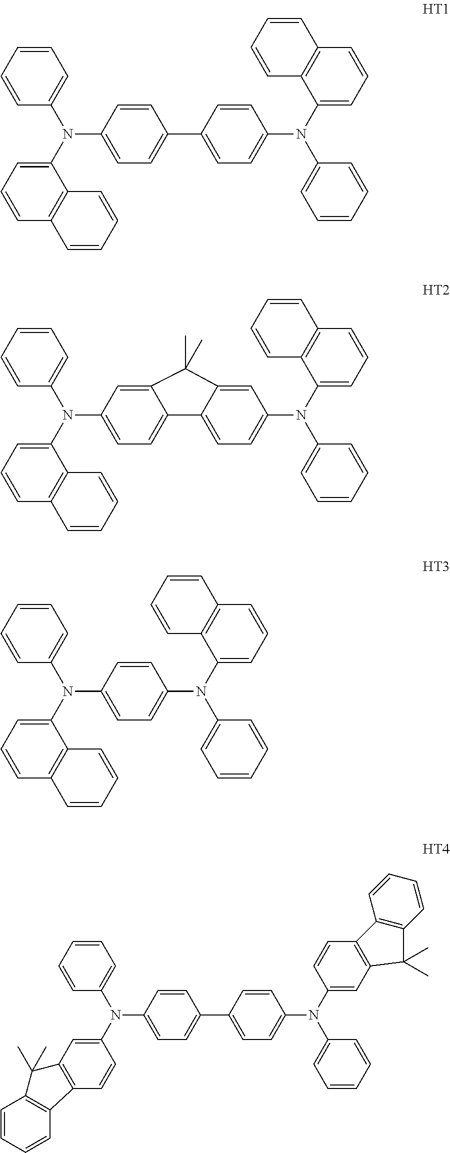 [SMILES: c1ccc(N(c2ccc(-c3ccc(N(c4ccccc4)c4cccc5ccccc45)cc3)cc2)c2cccc3ccccc23)cc1 ; CC1(C)c2cc(N(c3ccccc3)c3cccc4ccccc34)ccc2-c2ccc(N(c3ccccc3)c3cccc4ccccc34)cc21 ; c1ccc(N(c2ccc(N(c3ccccc3)c3cccc4ccccc34)cc2)c2cccc3ccccc23)cc1 ; CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

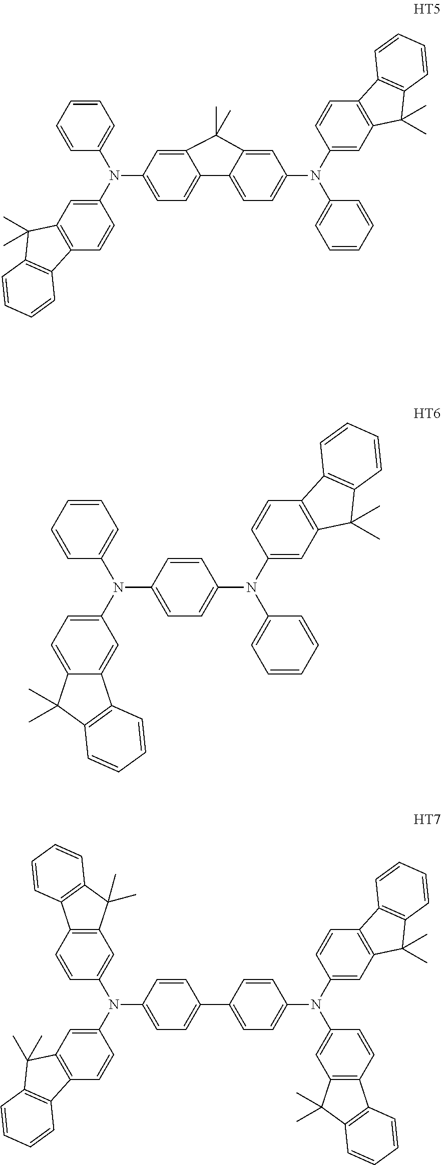 [SMILES: CC1(C)c2ccccc2-c2ccc(N(c3ccccc3)c3ccc4c(c3)C(C)(C)c3cc(N(c5ccccc5)c5ccc6c(c5)C(C)(C)c5ccccc5-6)ccc3-4)cc21 ; CC1(C)c2ccccc2-c2cc(N(c3ccccc3)c3ccc(N(c4ccccc4)c4ccc5c(c4)C(C)(C)c4ccccc4-5)cc3)ccc21 ; CC1(C)c2ccccc2-c2ccc(N(c3ccc(-c4ccc(N(c5ccc6c(c5)C(C)(C)c5ccccc5-6)c5ccc6c(c5)C(C)(C)c5ccccc5-6)cc4)cc3)c3ccc4c(c3)C(C)(C)c3ccccc3-4)cc21]

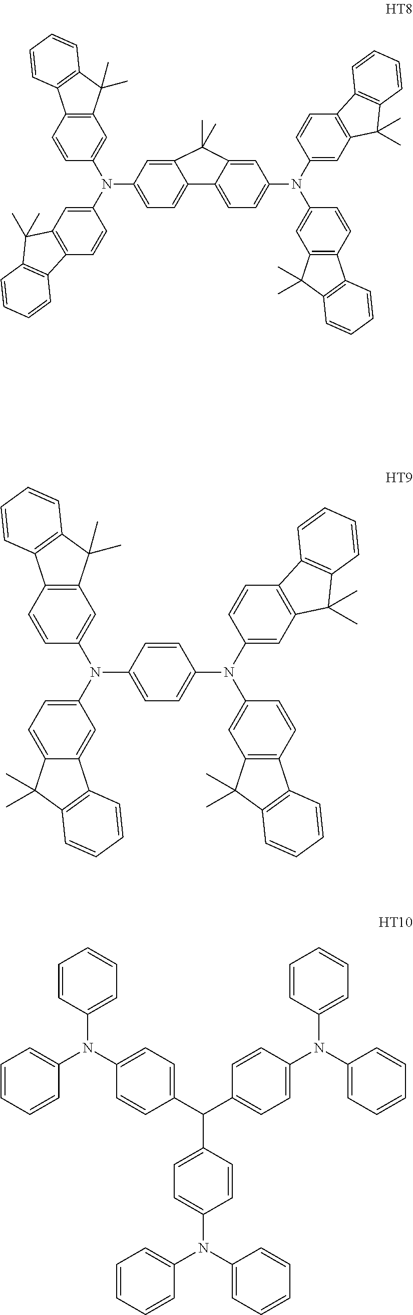 [SMILES: CC1(C)c2ccccc2-c2ccc(N(c3ccc4c(c3)C(C)(C)c3ccccc3-4)c3ccc4c(c3)C(C)(C)c3cc(N(c5ccc6c(c5)C(C)(C)c5ccccc5-6)c5ccc6c(c5)C(C)(C)c5ccccc5-6)ccc3-4)cc21 ; CC1(C)c2ccccc2-c2cc(N(c3ccc(N(c4ccc5c(c4)C(C)(C)c4ccccc4-5)c4ccc5c(c4)C(C)(C)c4ccccc4-5)cc3)c3ccc4c(c3)C(C)(C)c3ccccc3-4)ccc21 ; c1ccc(N(c2ccccc2)c2ccc(C(c3ccc(N(c4ccccc4)c4ccccc4)cc3)c3ccc(N(c4ccccc4)c4ccccc4)cc3)cc2)cc1]

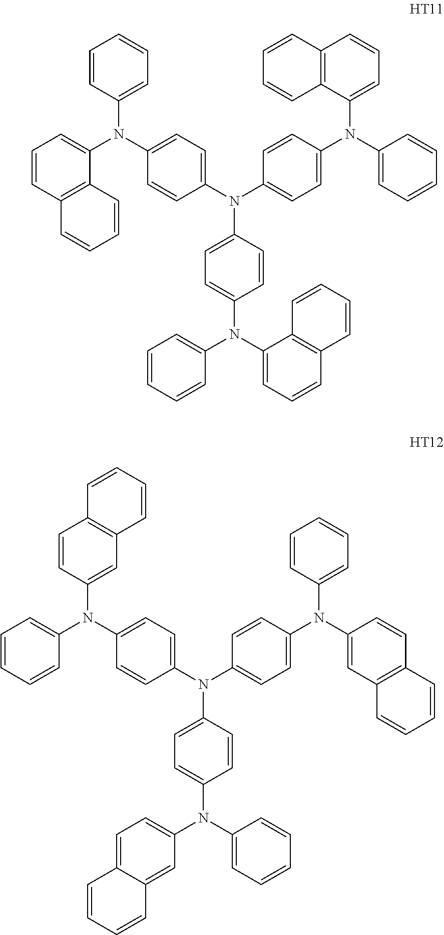 [SMILES: c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

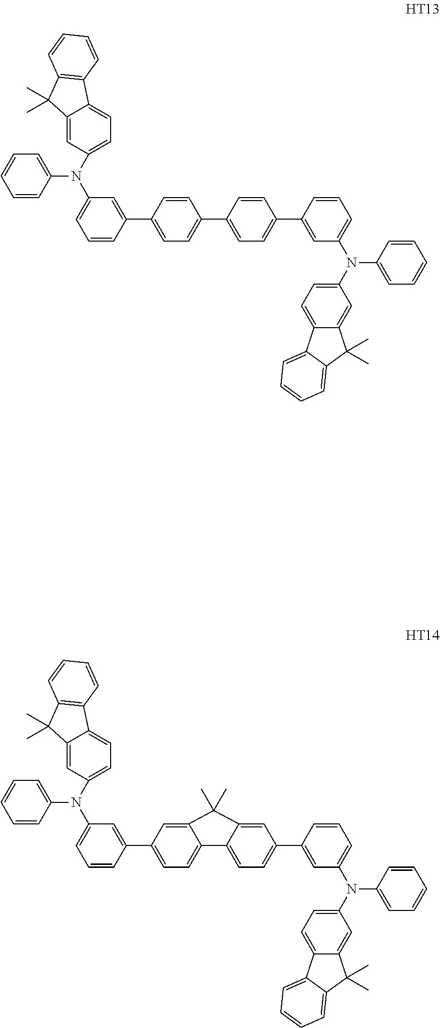 [SMILES: CC1(C)c2ccccc2-c2ccc(N(c3ccccc3)c3cccc(-c4ccc(-c5ccc(-c6cccc(N(c7ccccc7)c7ccc8c(c7)C(C)(C)c7ccccc7-8)c6)cc5)cc4)c3)cc21 ; CC1(C)c2cc(-c3cccc(N(c4ccccc4)c4ccc5c(c4)C(C)(C)c4ccccc4-5)c3)ccc2-c2ccc(-c3cccc(N(c4ccccc4)c4ccc5c(c4)C(C)(C)c4ccccc4-5)c3)cc21]

### Thickness Adjustment Layer

The red luminescent layer 3R, the green luminescent layer 3G and the blue luminescent layer 3B are formed on the first charge transport layer 2. These luminescent layers are formed through metal masks. In the structure shown in FIG. 2A, the thickness adjustment layer 6 is formed between the first charge transport layer 2 and the red luminescent layer 3R by vapor deposition through a metal mask.

In the structures shown in FIGS. 2A and 2B, the thickness adjustment layer 6 can be made of a hole transport material, and this material may be the same as or different from the material of the first charge transport layer 2. In the structure shown in FIGS. 3A and 3B in which the thickness adjustment layer 6 is disposed on the cathode side, the thickness adjustment layer 6 can be made of the same material as the host material used in the red luminescent layer 3R.

### Red Luminescent Layer

The red luminescent layer 3R can contain a host material and a luminescent dopant, and an assistant dopant. Examples of the host material of the red luminescent layer 3R include compounds expressed by the following structural formulas:

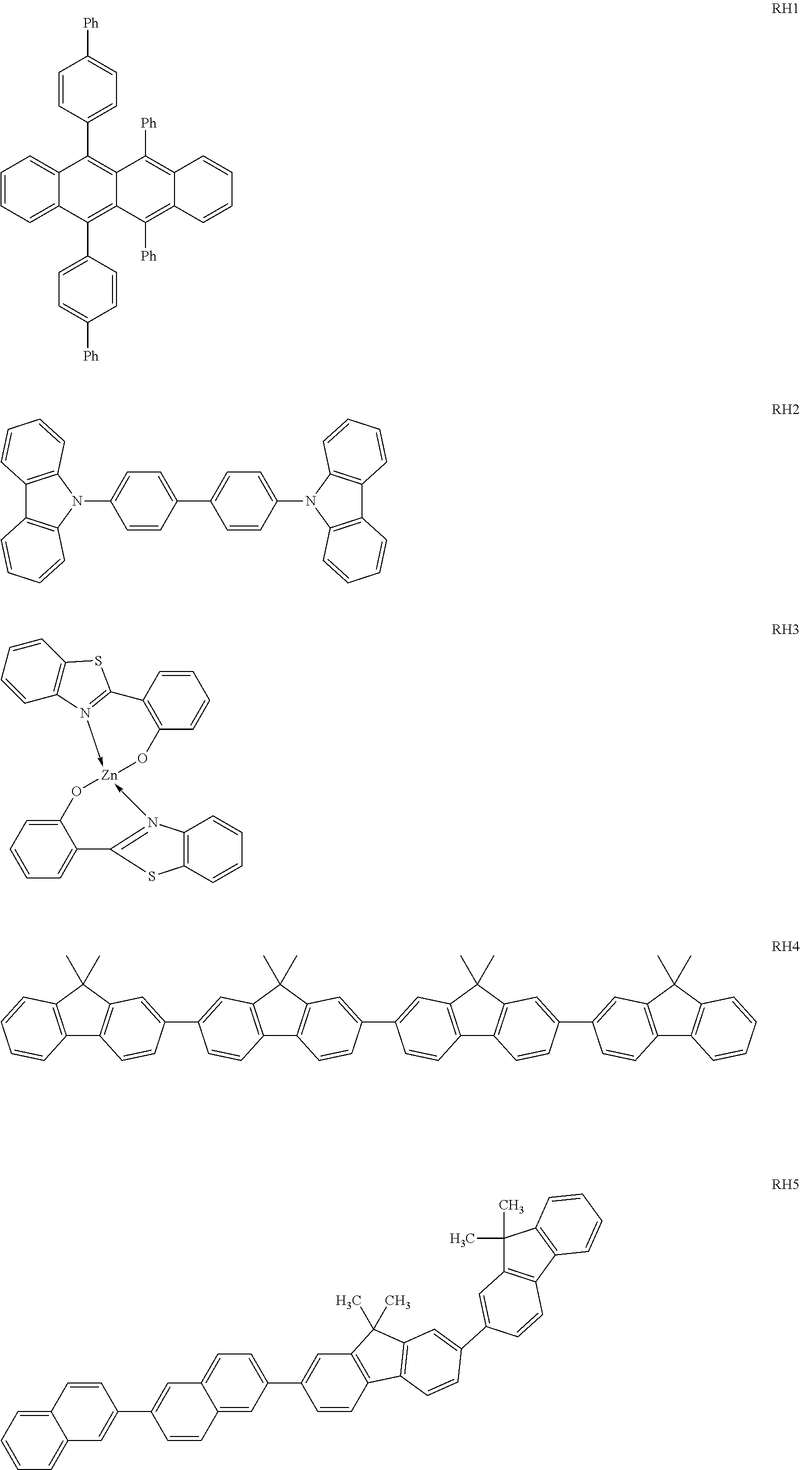

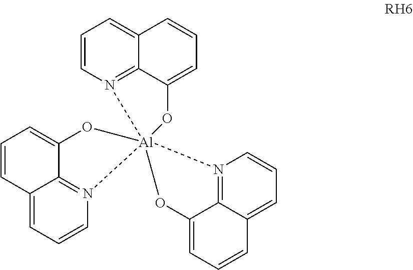

Examples of the luminescent dopant of the red luminescent layer 3R include compounds expressed by the following structural formulas, and compounds RD7 to RD11, which emit phosphorescence, are particularly suitable. The use of these compounds results in high emission efficiency. When any of the red phosphorescent materials of compounds RD7 to RD11 is used, the emission position is likely to lie at the boundary of the red luminescent layer on the hole transport layer side, in many cases, as shown in FIGS. 2A and 2B.

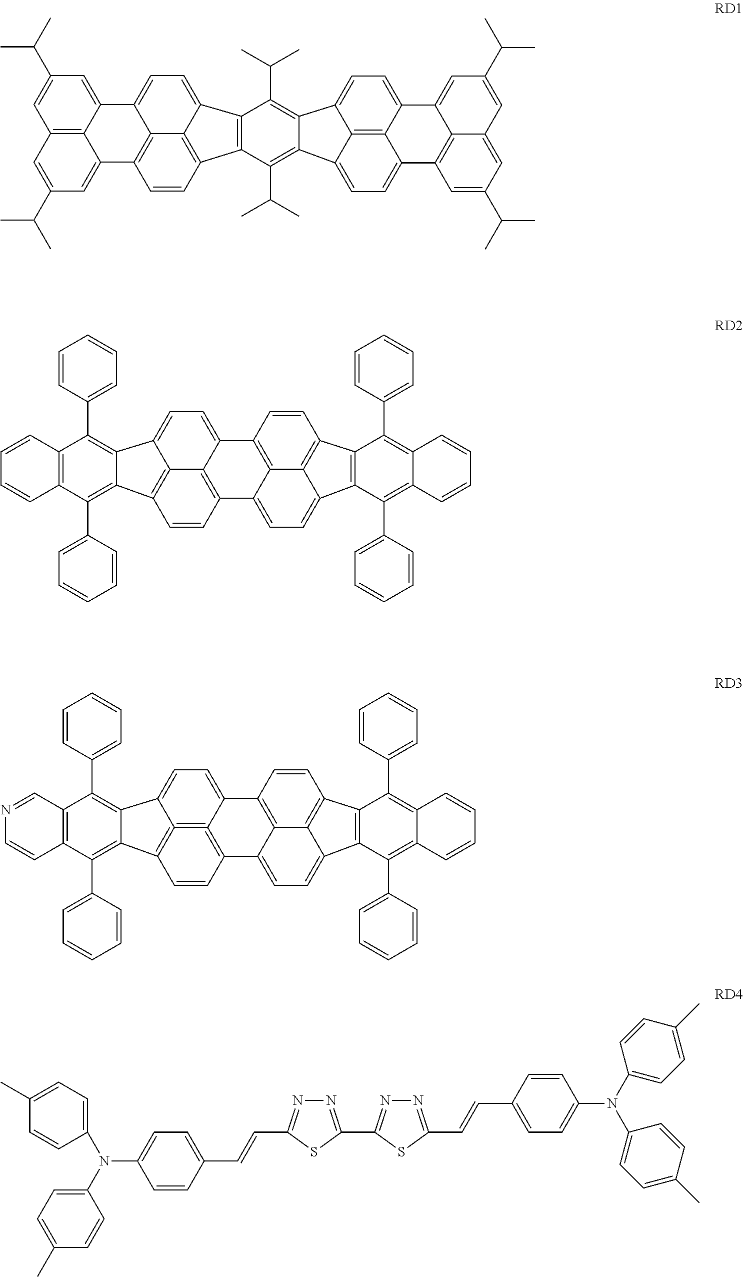

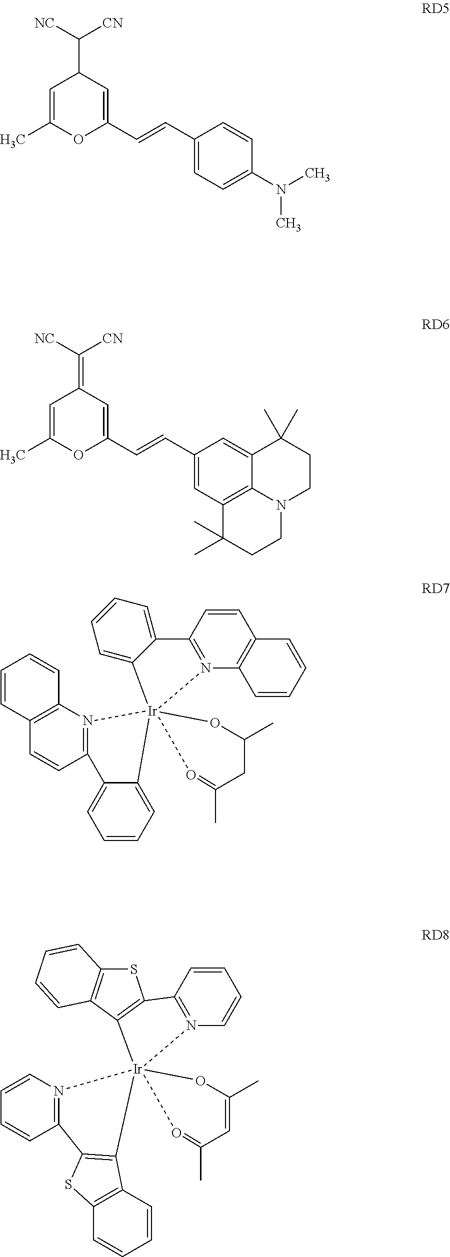

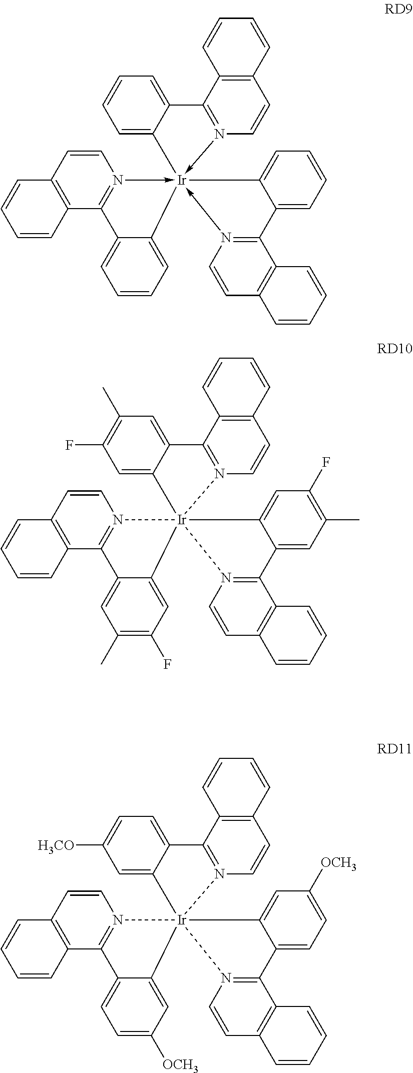

When the thickness adjustment layer 6 is disposed on the anode side of the luminescent layer 3R, the assistant dopant can be a known hole transport material, such as arylamine, and the same material as the thickness adjustment layer 6 can be used. If the assistant dopant and the material of the thickness adjustment layer 6 are the same, holes are easily injected to the red luminescent layer, and consequently, the voltage of the red organic EL element can be reduced effectively.

### Green Luminescent Layer

The green luminescent layer 3G contains a host material, a luminescent dopant and an assistant dopant. These materials may satisfy the following relationship (I):

LUMO_{Gh}<LUMO_{Ga}<LUMO_{Ge}<HOMO_{Ga}<HOMO_{Gh}<HOMO_{Ge} (I)

In relationship (I), LUMO_{Gh}, LUMO_{Ge} and LUMO_{Ga} represent the absolute values of the lowest unoccupied molecular orbital (LUMO) energy levels of the host material, the luminescent dopant and the assistant dopant in the green luminescent layer, respectively. HOMO_{Gh}, HOMO_{Ge} and HOMO_{Ga} represent the absolute values of the highest occupied molecular orbital (HOMO) energy levels of the host material, the luminescent dopant and the assistant dopant in the green luminescent layer, respectively.

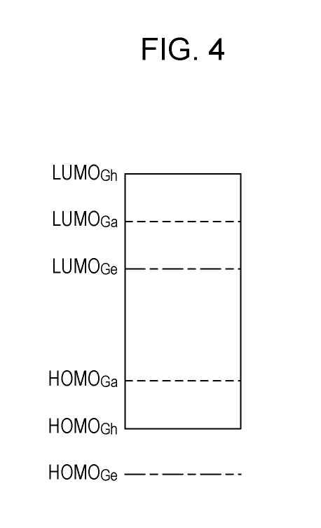

FIG. 4 shows an exemplary energy band diagram of the green luminescent layer 3G satisfying relationship (I). In the green luminescent layer 3G, the luminescent dopant content is 10% by weight or less and the assistant dopant content is 10% to 90% by weight.

In general, many of the green luminescent layers are of electron transport type, and their emission position lies at the interface with the hole transport layer. On the other hand, in the luminescent layer having the energy bands shown in FIG. 4, electrons are trapped at the LUMO energy level of the luminescent dopant, whose content in the green luminescent layer 3G is 10% or less, and accordingly, electron transport is not easy. Also, holes are trapped at the HOMO energy level of the assistant dopant, and accordingly, the transport of holes, as well as electrons, is not easy. If the assistant dopant content is as low as the luminescent dopant content, the recombination position is at the vicinity of the center of the luminescent layer because electrons and holes have similar mobilities. However, holes are allowed to move more easily than electrons by increasing the assistant dopant content relative to the luminescent dopant content, and consequently, the recombination position is shifted to the cathode side. In contrast, electrons are allowed to move more easily than holes by reducing the assistant dopant content relative to the luminescent dopant content, and the recombination position is shifted to the anode side. Thus, the recombination position of electrons and holes can be controlled within the luminescent layer by adjusting the assistant dopant content, and consequently, the emission position is controlled by the assistant dopant content. The emission position also changes depending on the hole mobilities of the assistant dopant and the luminescent dopant. However, when the assistant dopant content is higher than the luminescent dopant content, the emission position tends to shift to the cathode side from the center of the luminescent layer, and when the assistant dopant content is lower than the luminescent dopant content, the emission position tends to shift to the anode side from the center of the luminescent layer. In embodiments of the present invention, the assistant dopant can be used at a higher content than the luminescent dopant so that the emission position can shift to the cathode side from the center of the luminescent layer. Thus the luminous efficiency can be enhanced by adjusting the emission position and the reflection plane. More specifically, in the green luminescent layer 3G, the luminescent dopant content is 10% by weight or less and the assistant dopant content is 10% to 90% by weight. The assistant dopant content is preferably 30% to 70% by weight.

The HOMO and LUMO values are represented by the absolute values of their energy levels. The HOMO, or highest occupied molecular orbital, is measured by photoelectron spectroscopy in air (with AC-2, manufactured by Riken Keiki). The LUMO is calculated by subtracting the band gap obtained from the absorption end of the absorption spectrum from the HOMO value measured by the above method.

Examples of the host material of the green luminescent layer 3G include compounds expressed by the following structural formulas:

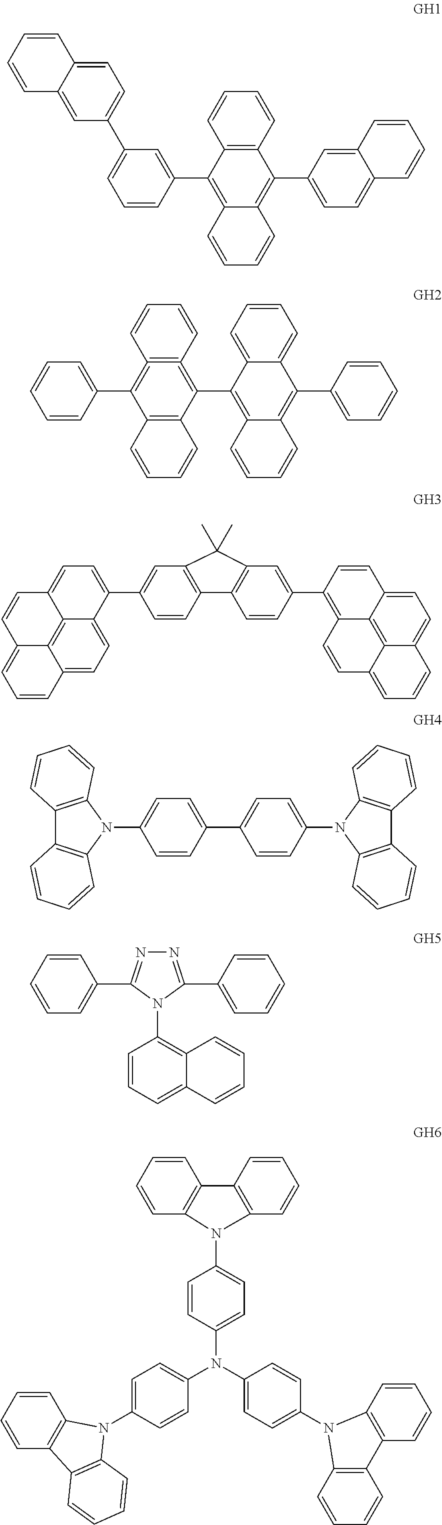

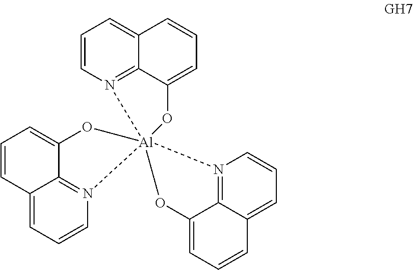

Examples of the luminescent dopant of the green luminescent layer 3G include compounds expressed by the following structural formulas:

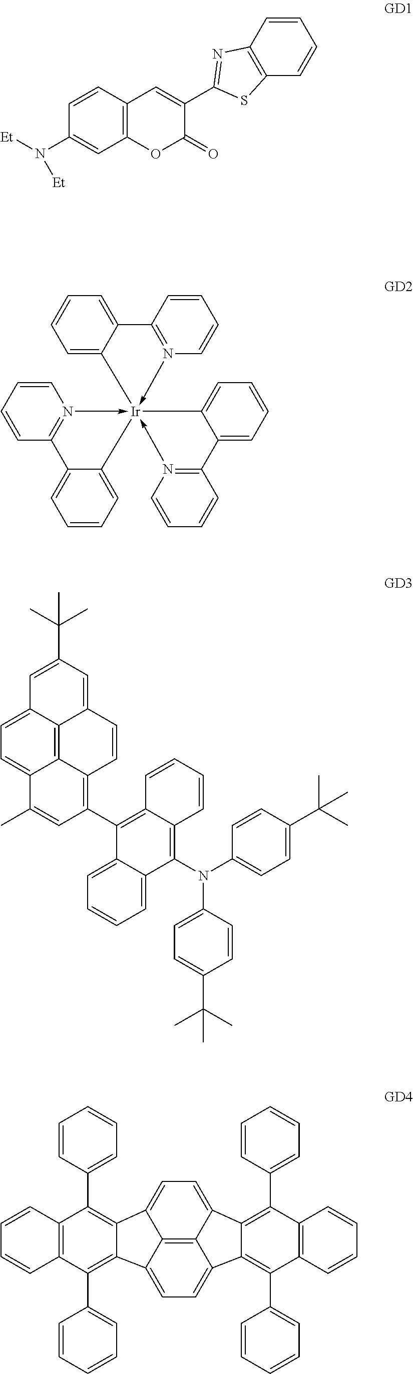

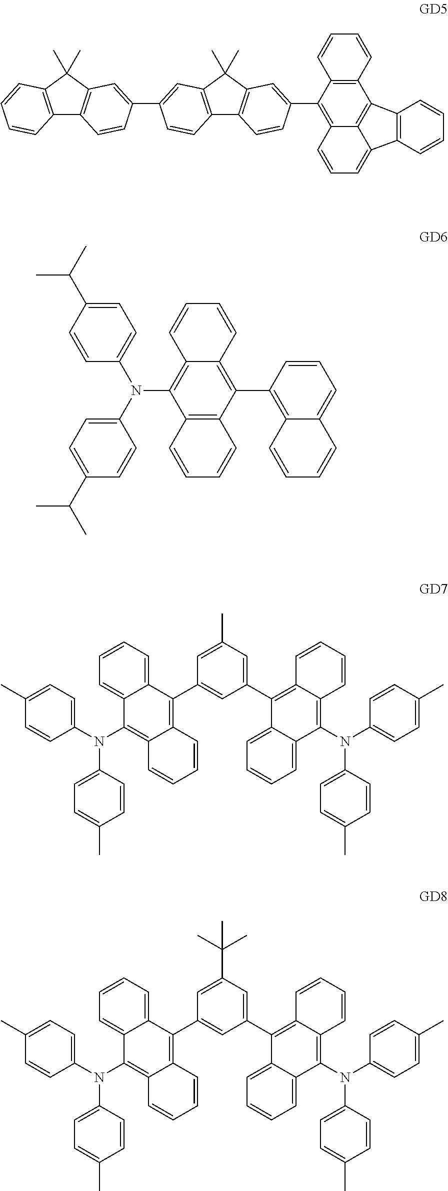

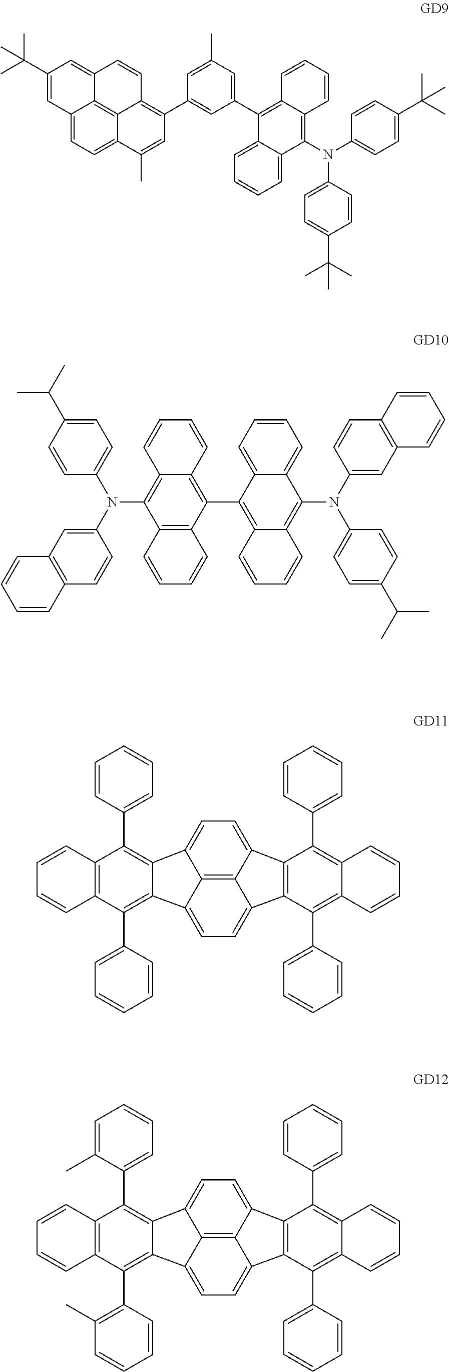

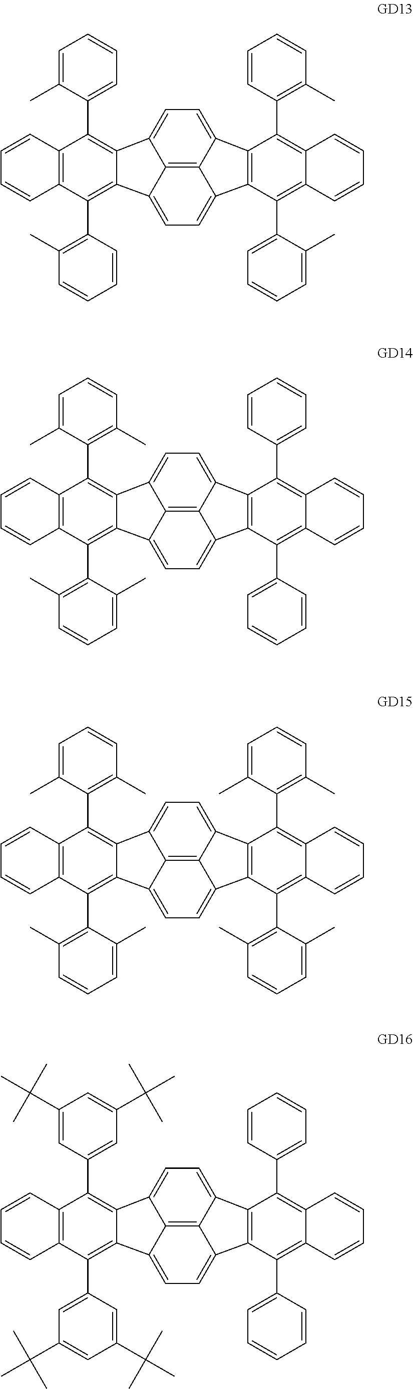

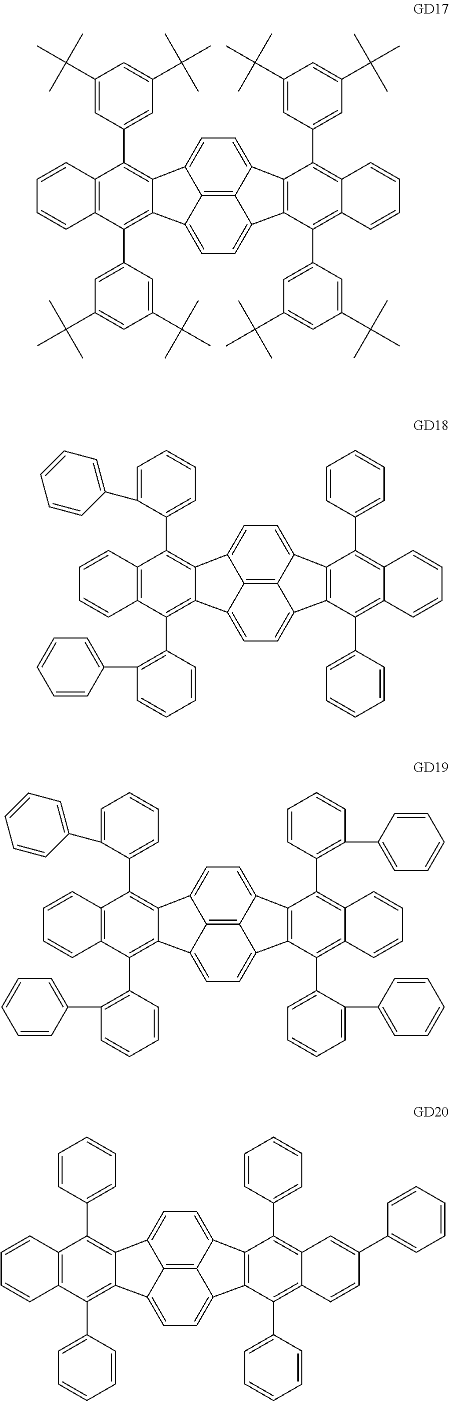

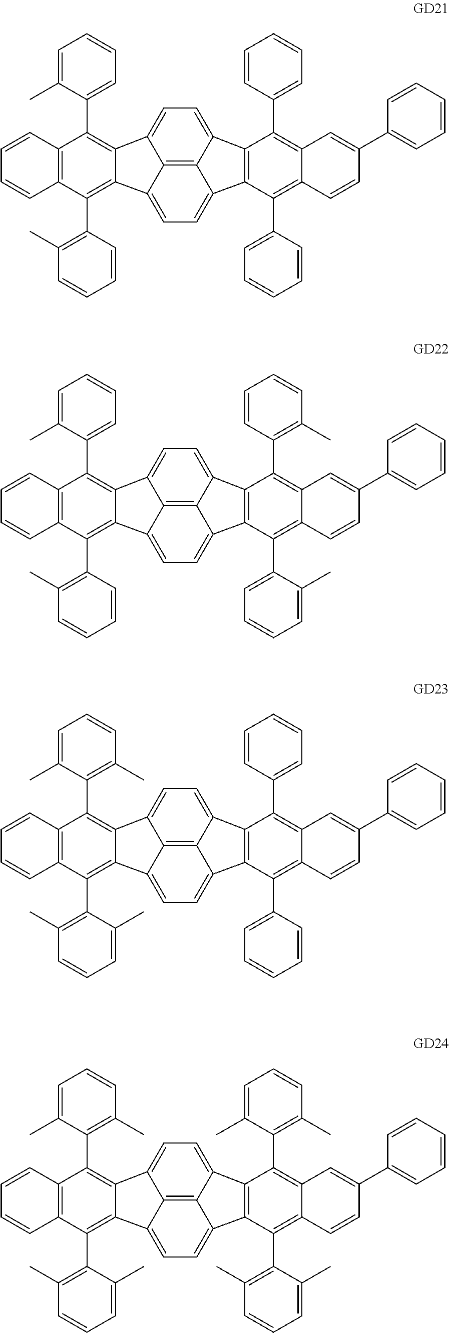

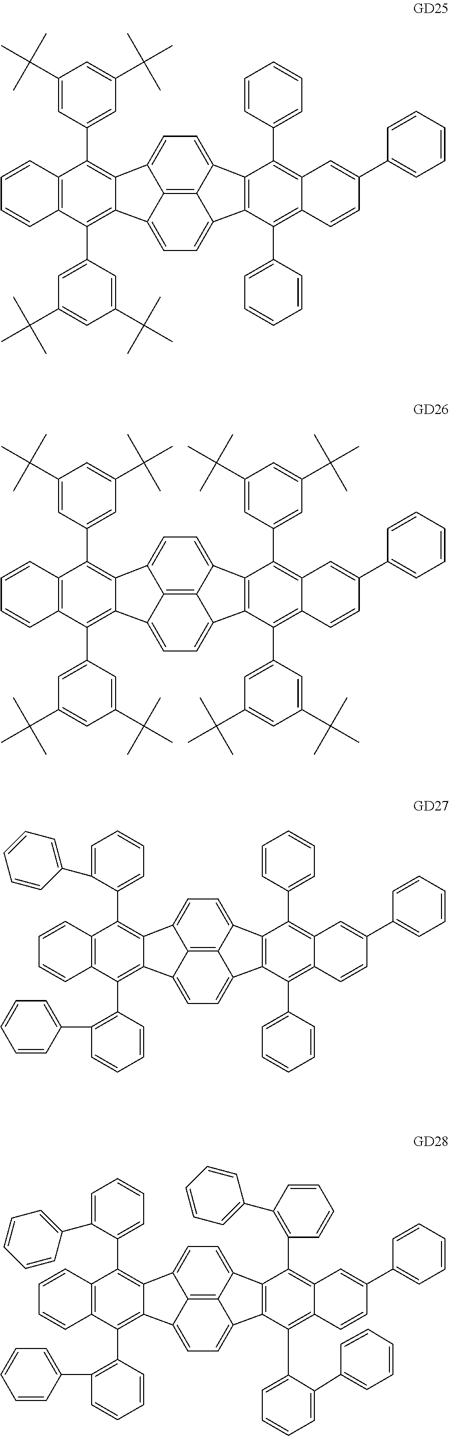

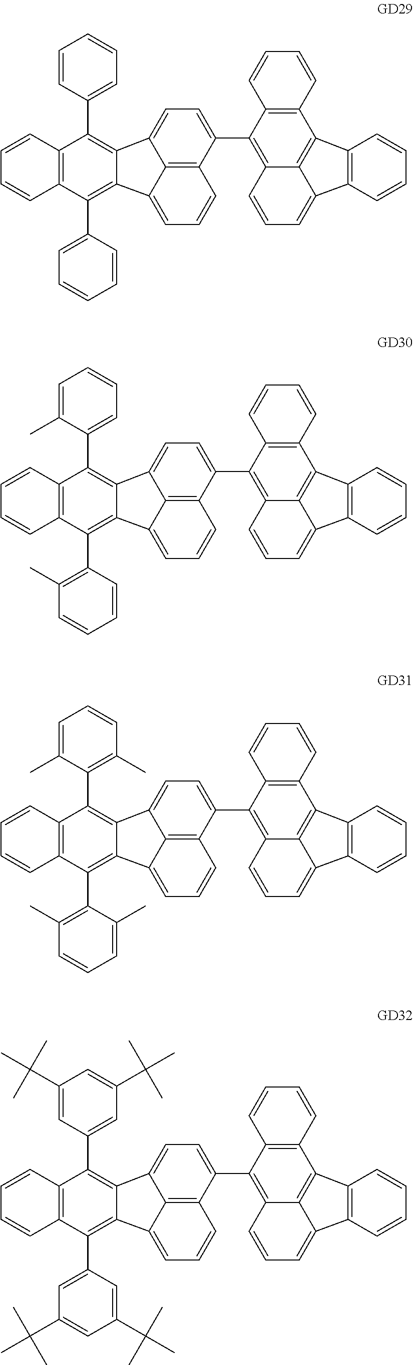

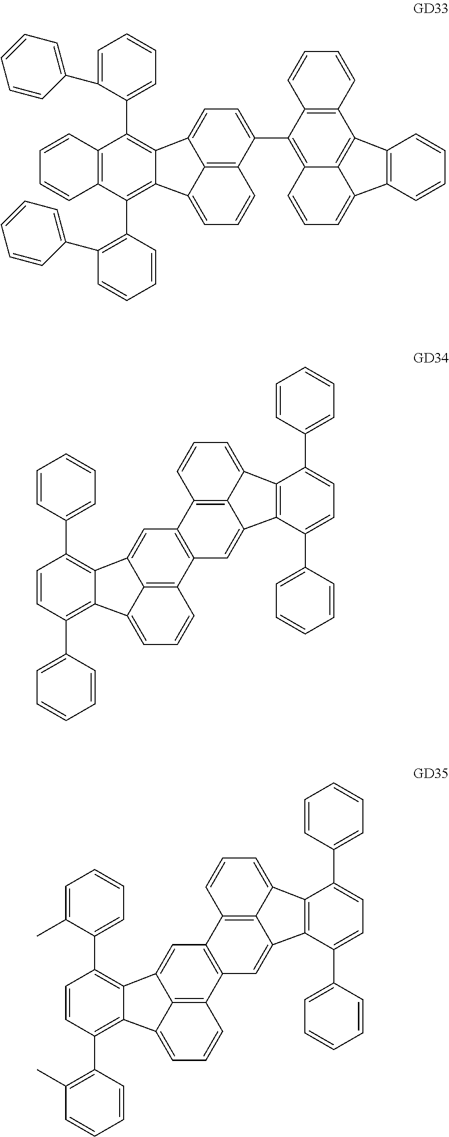

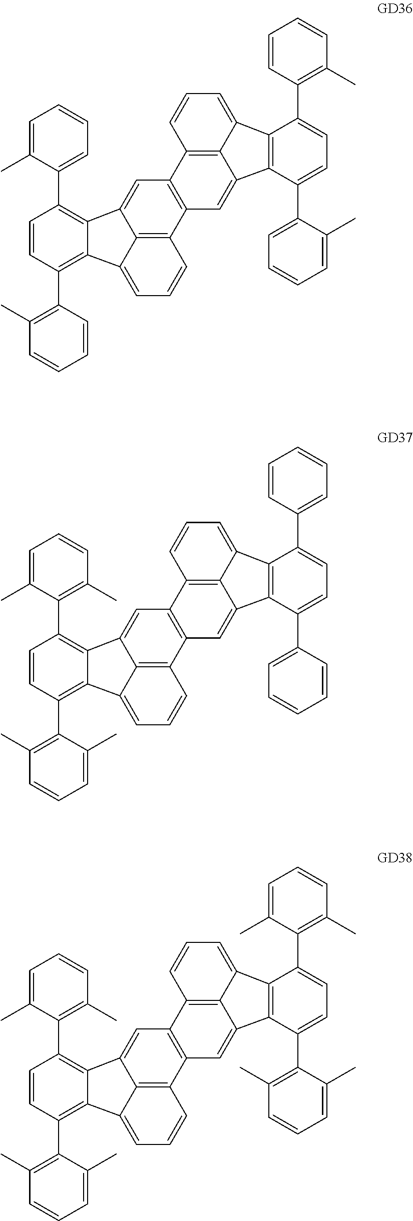

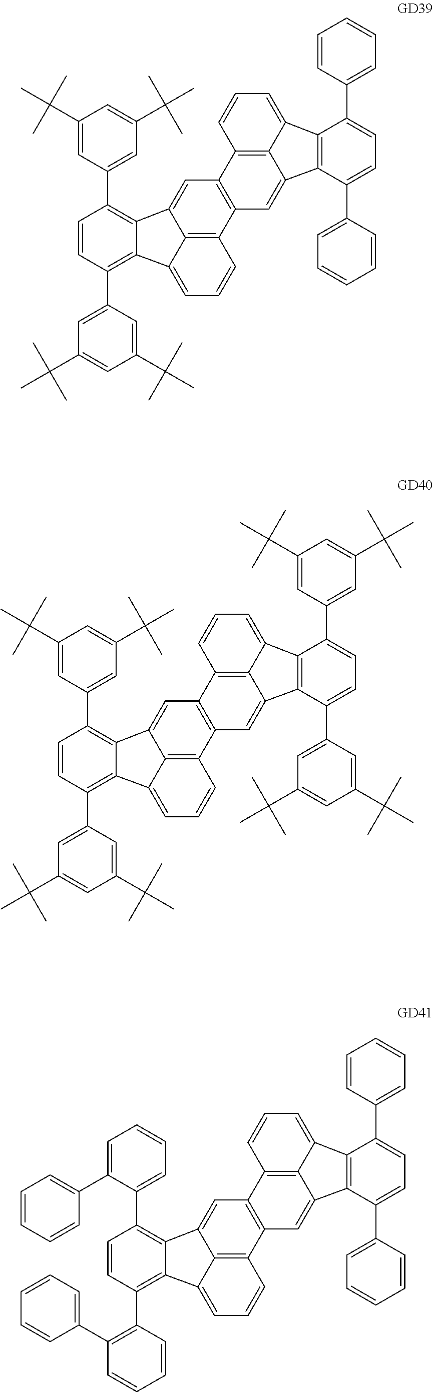

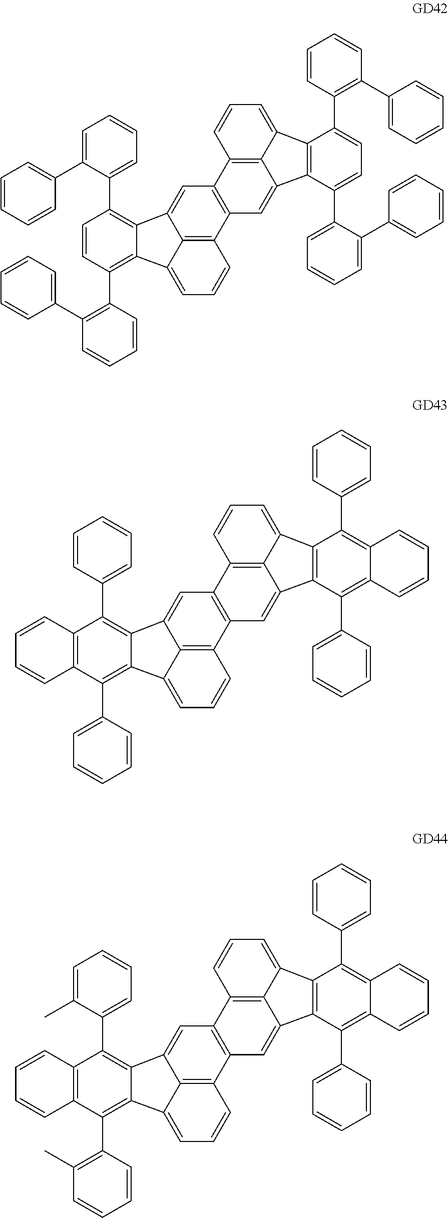

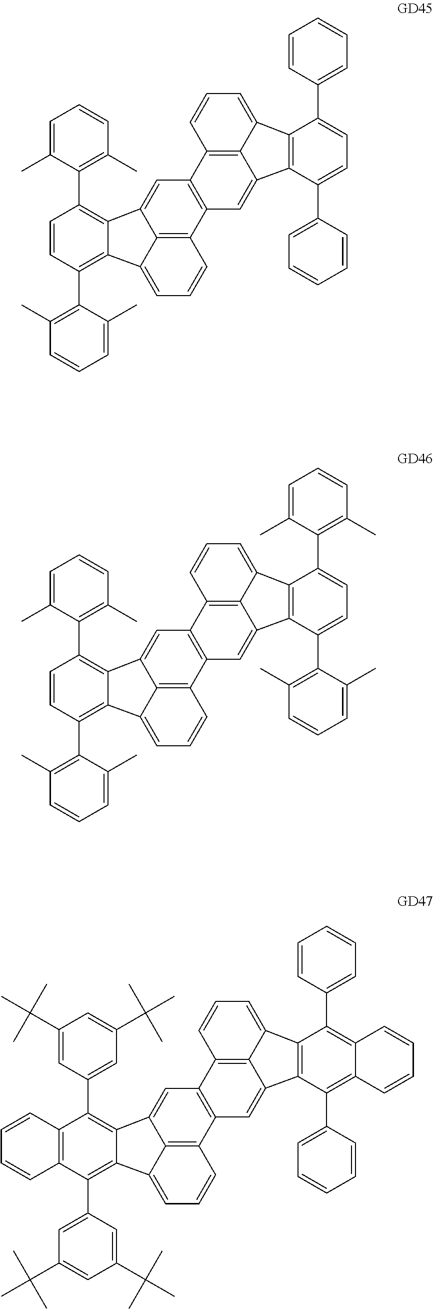

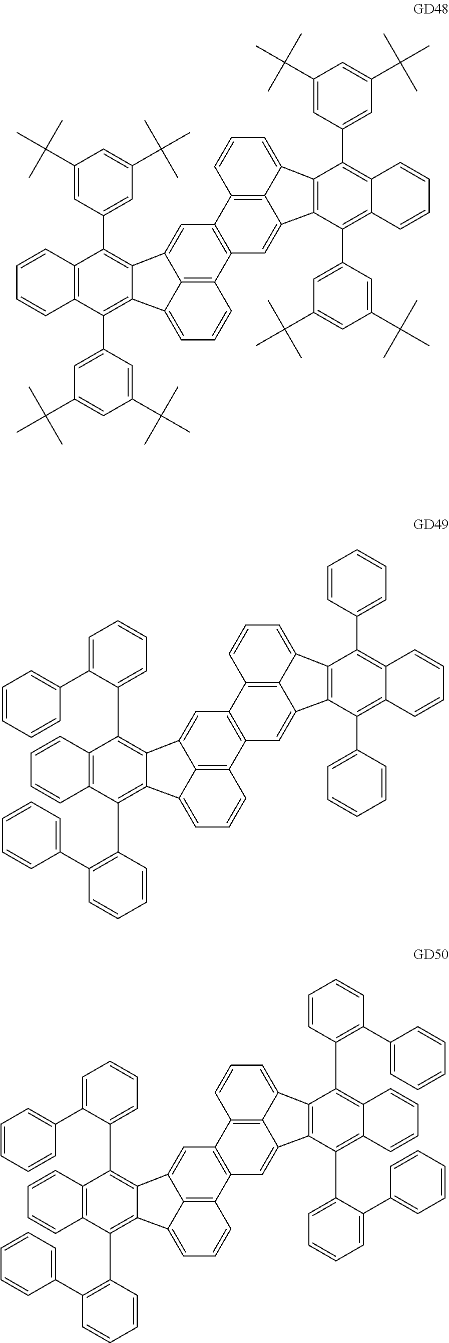

Examples of the assistant dopant of the green luminescent layer 3G include compounds expressed by the following structural formulas:

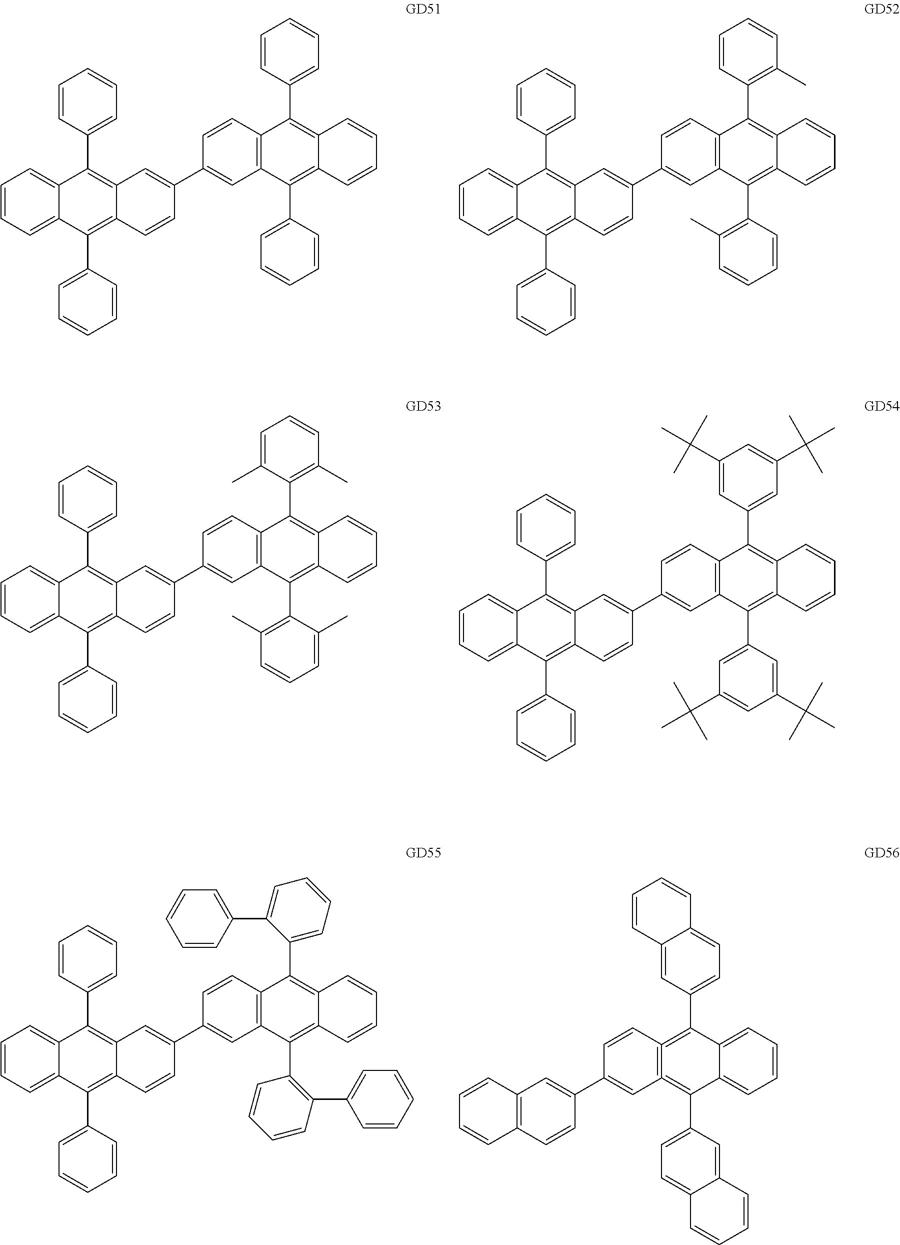

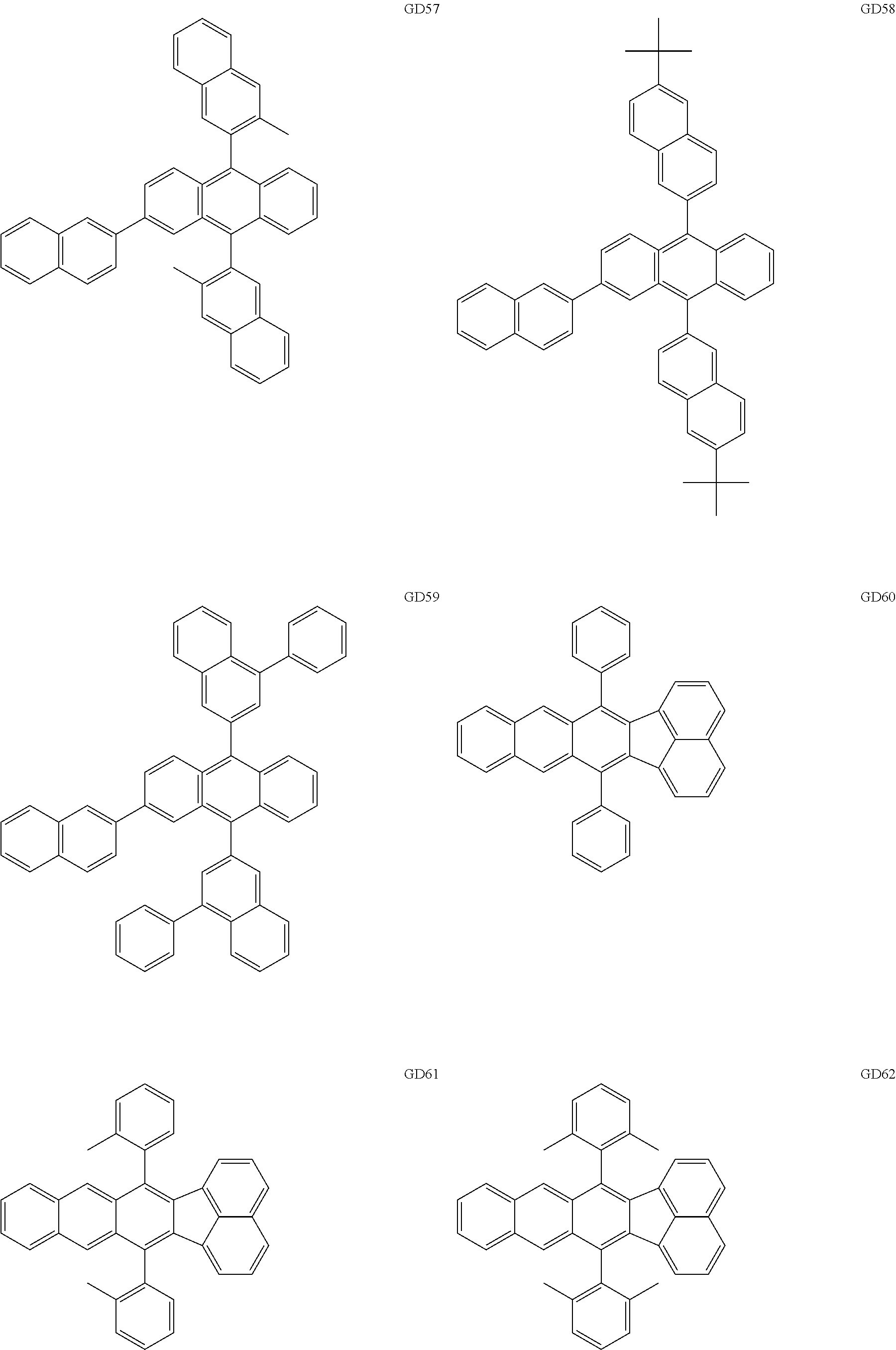

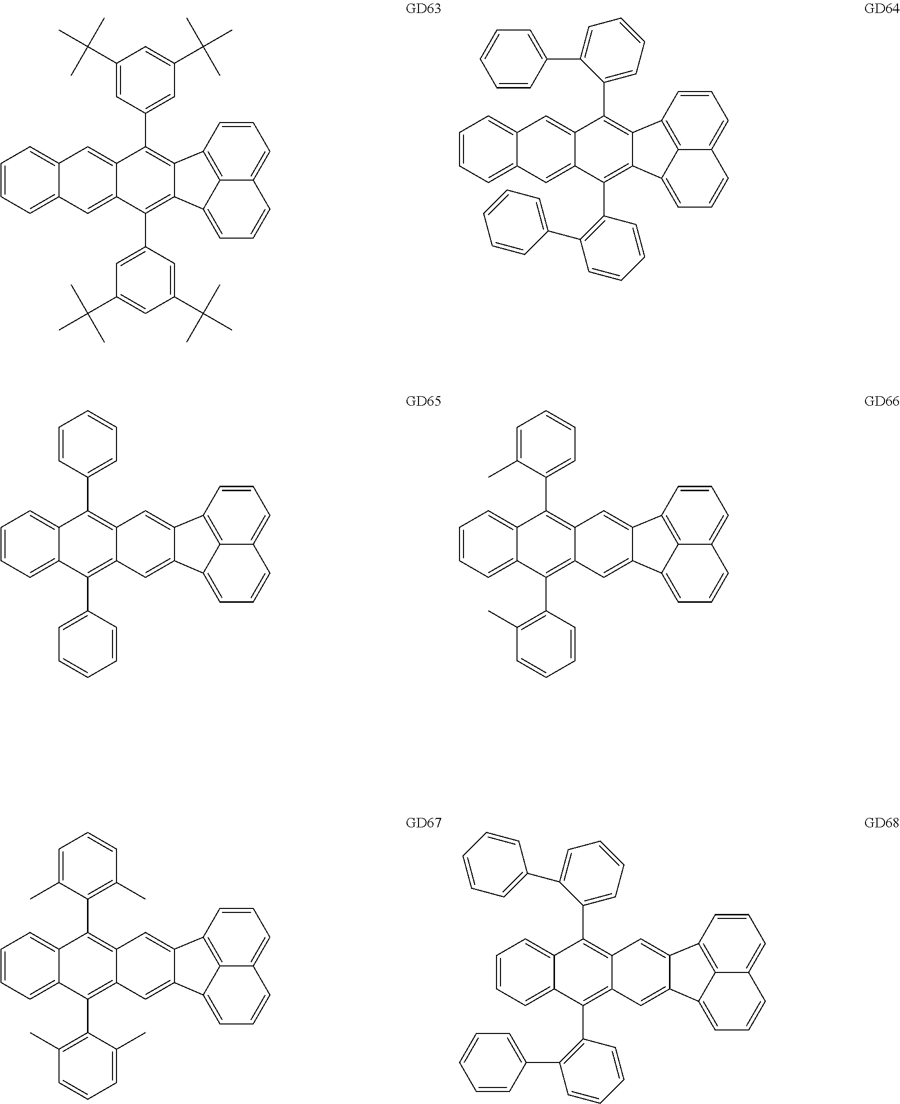

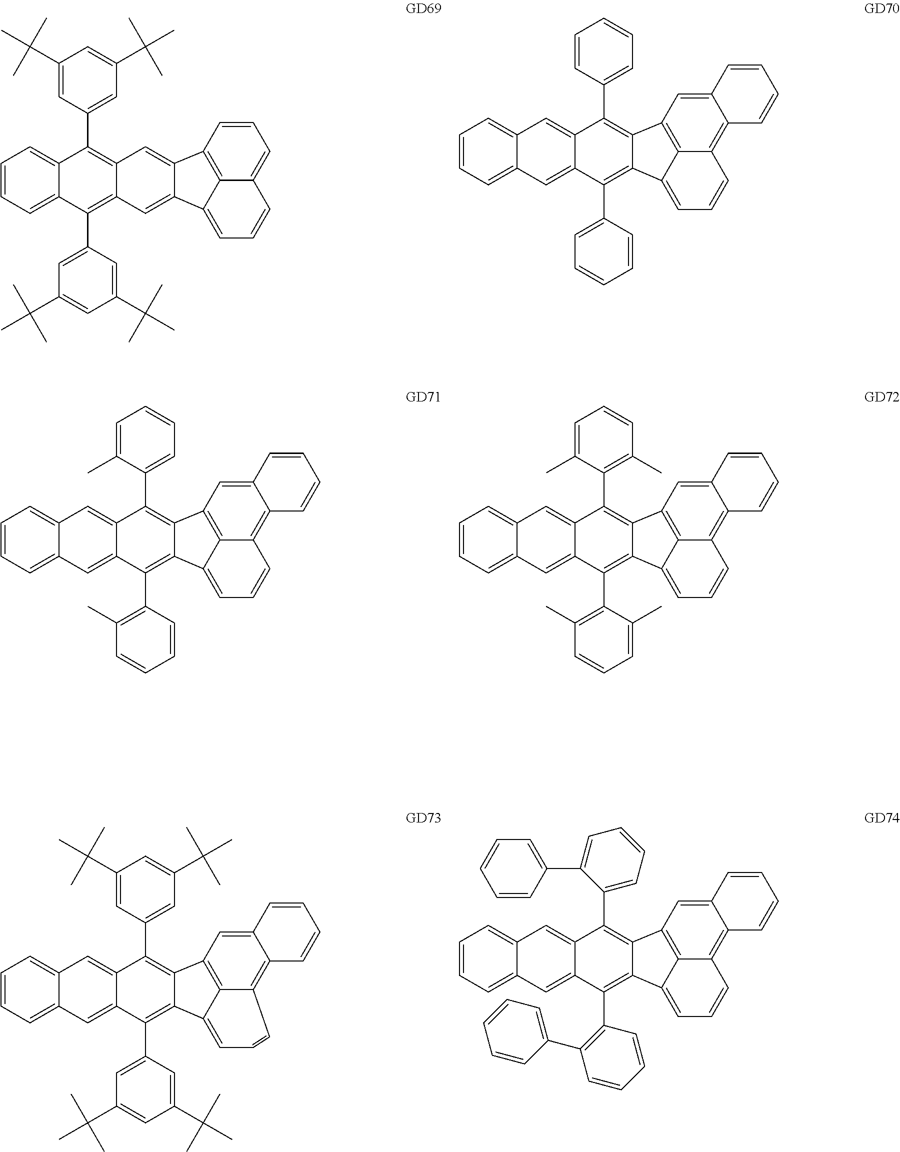

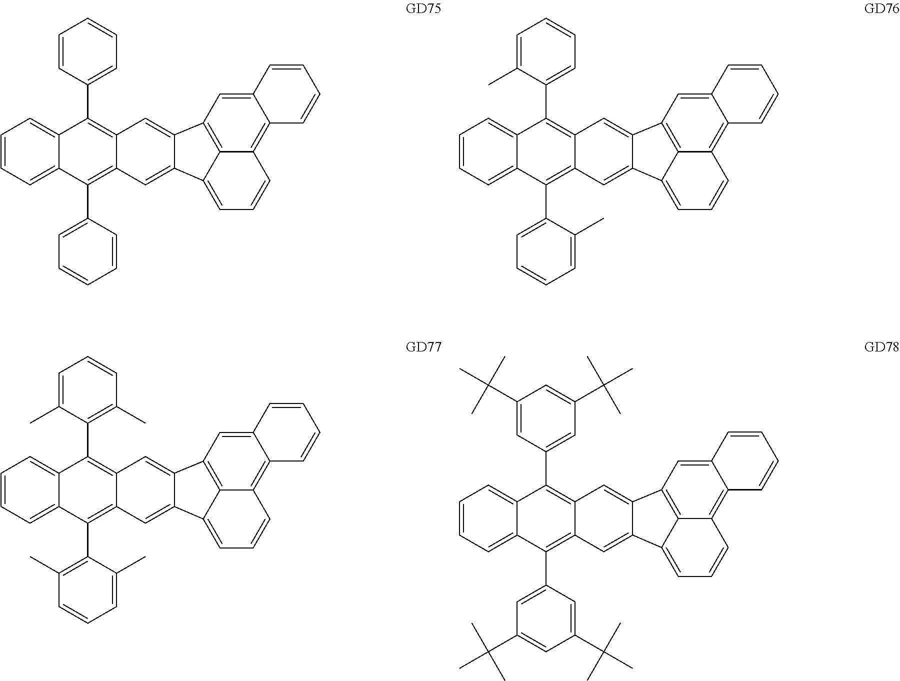

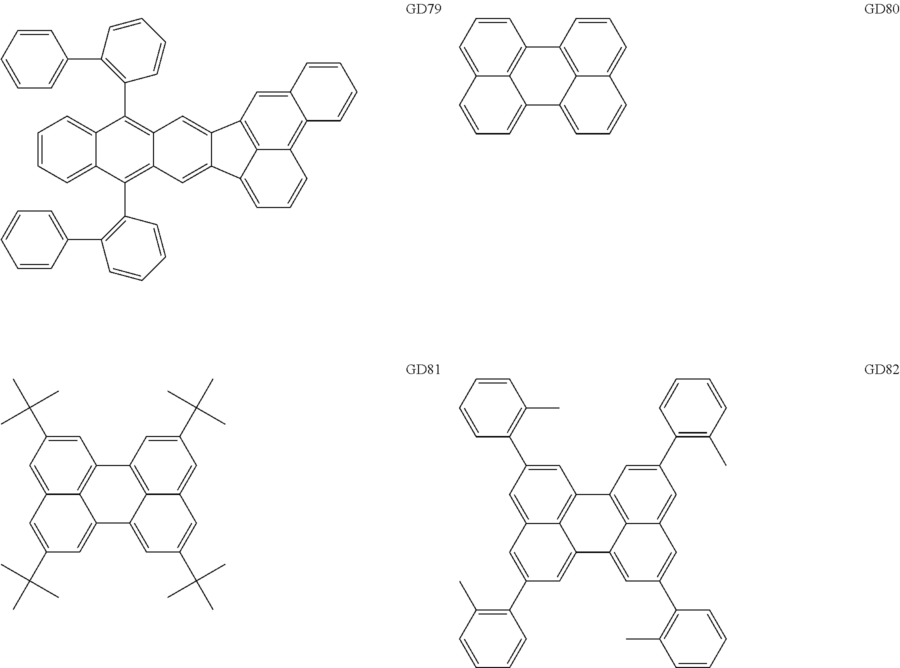

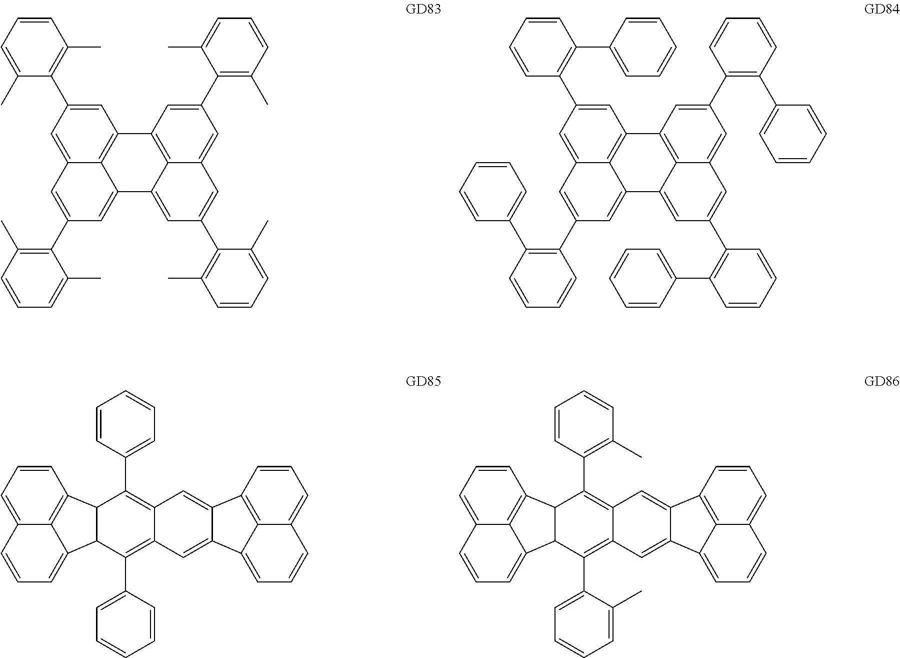

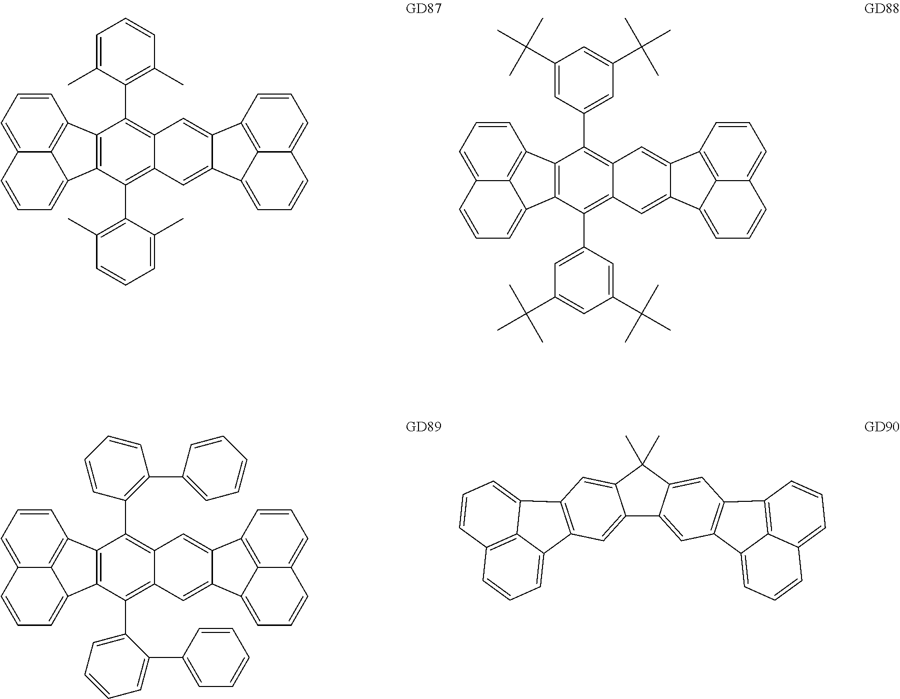

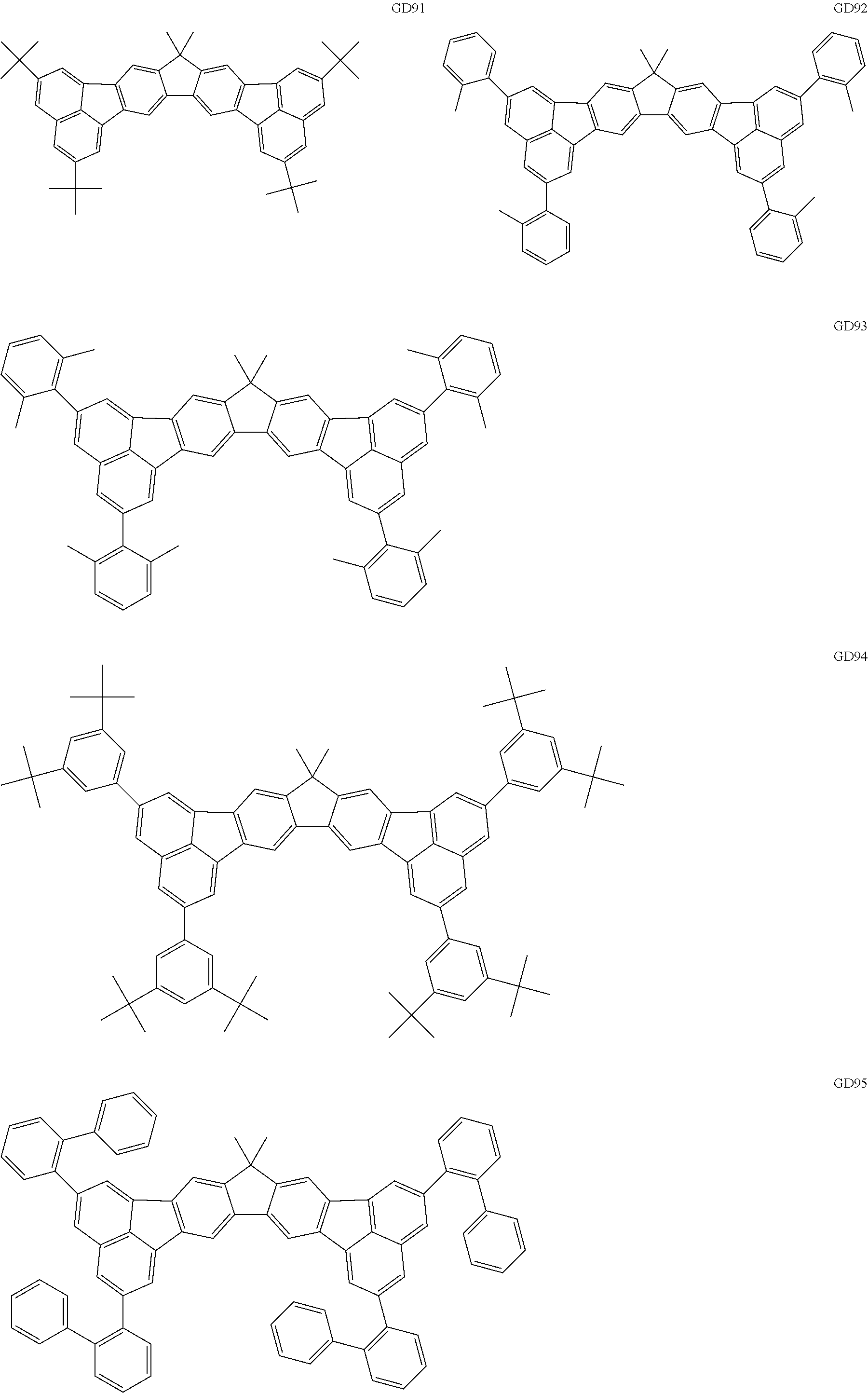

### Blue Luminescent Layer

The blue luminescent layer 3B also can contain a host material and a luminescent dopant. Examples of the host material of the blue luminescent layer 3B include compounds expressed by the following structural formulas:

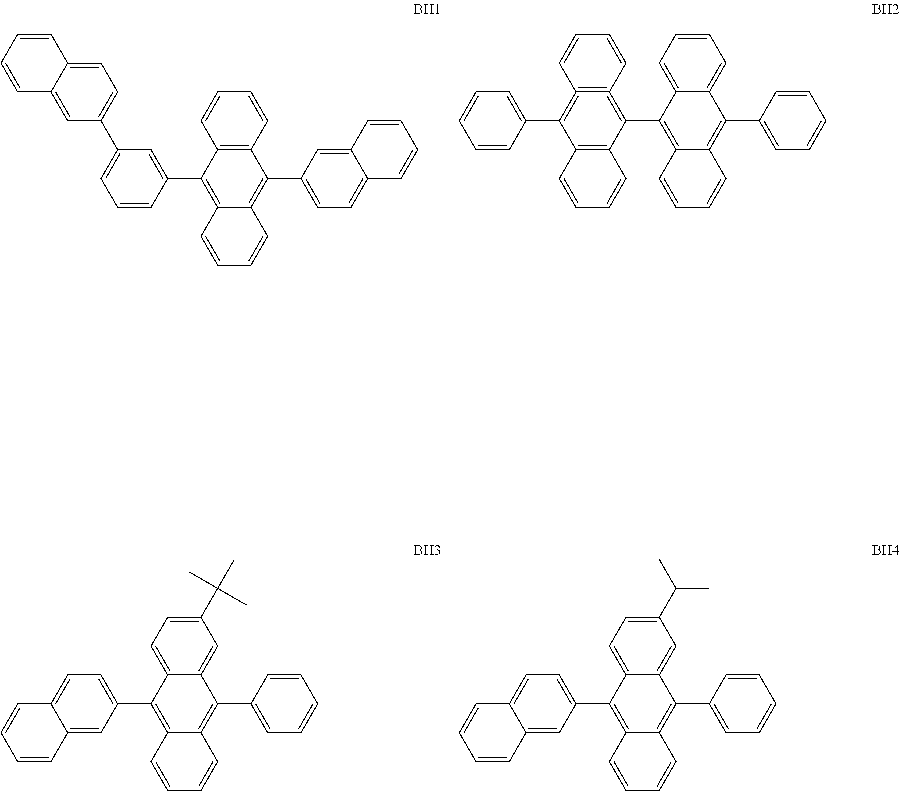

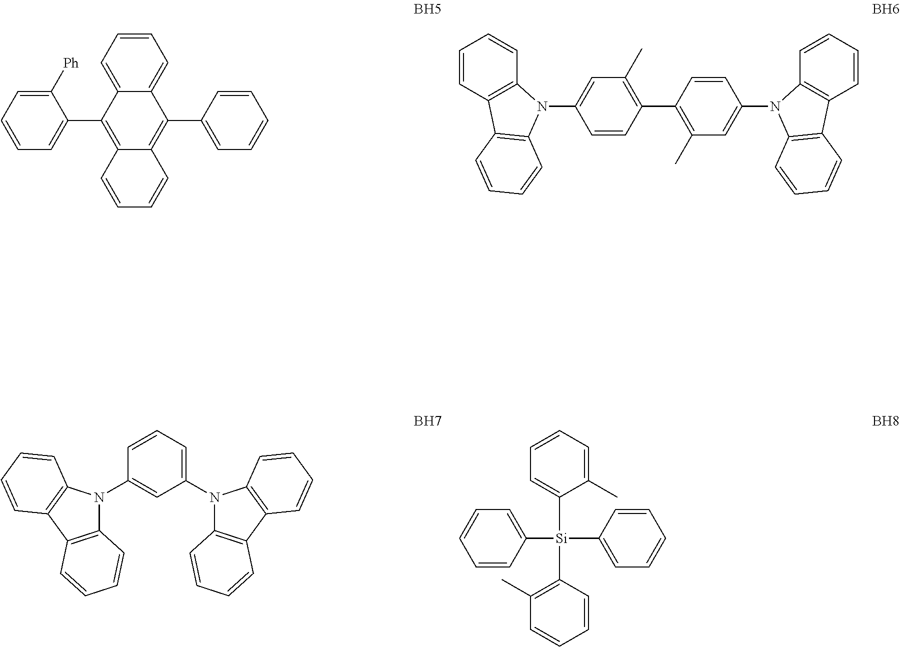

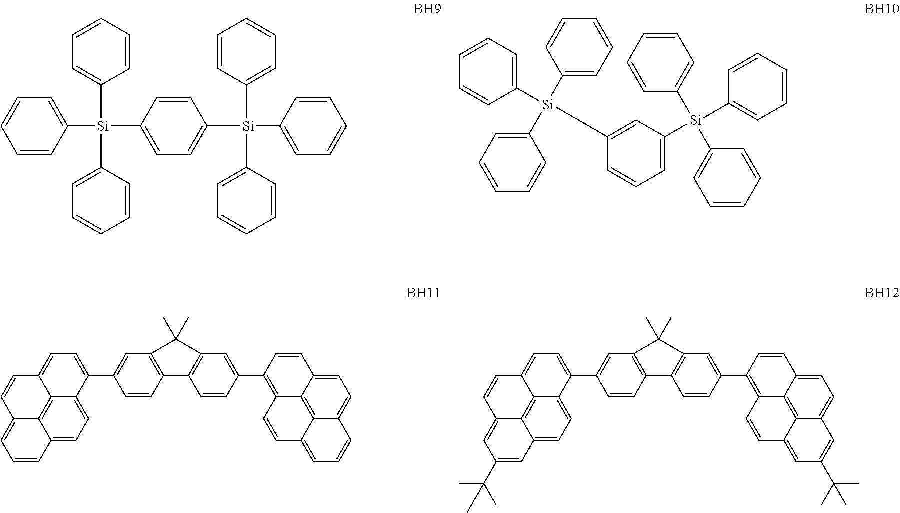

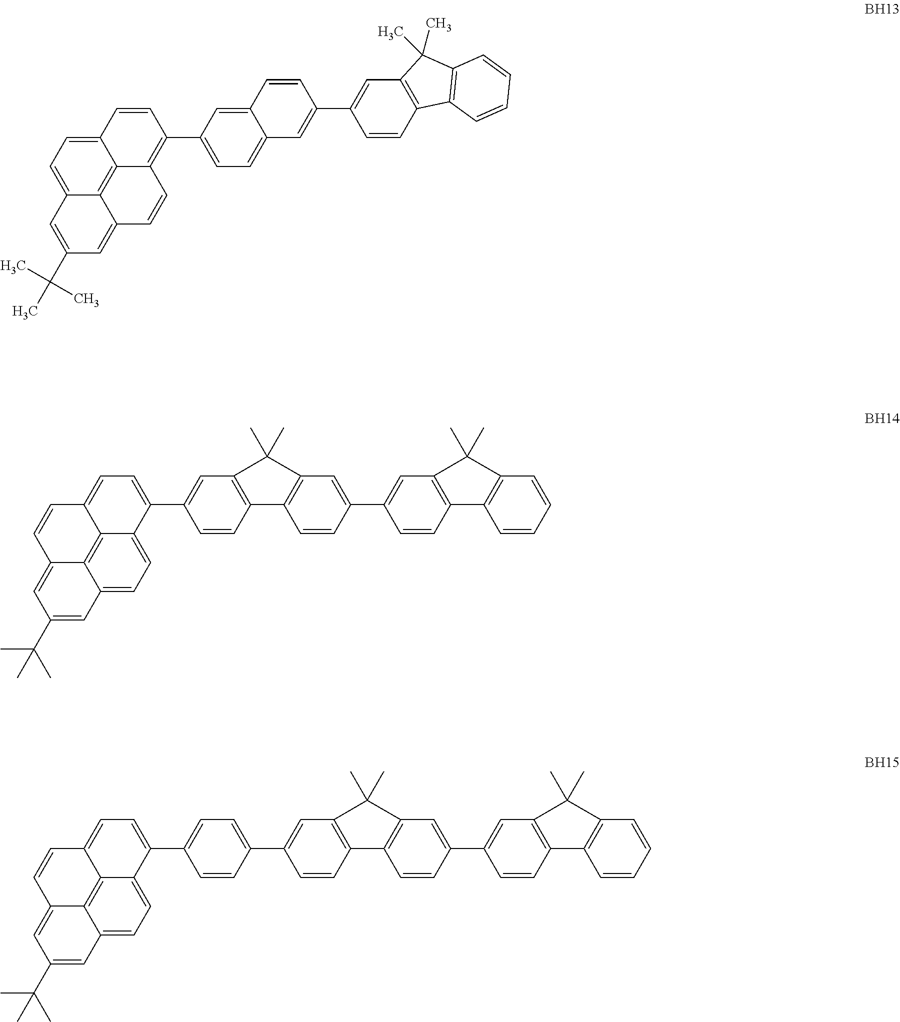

Examples of the luminescent dopant of the blue luminescent layer 3B include compounds expressed by the following structural formulas, and compounds BD12 to BD18, which have five-membered rings, are particularly suitable. The use of these compounds results in high emission efficiency.

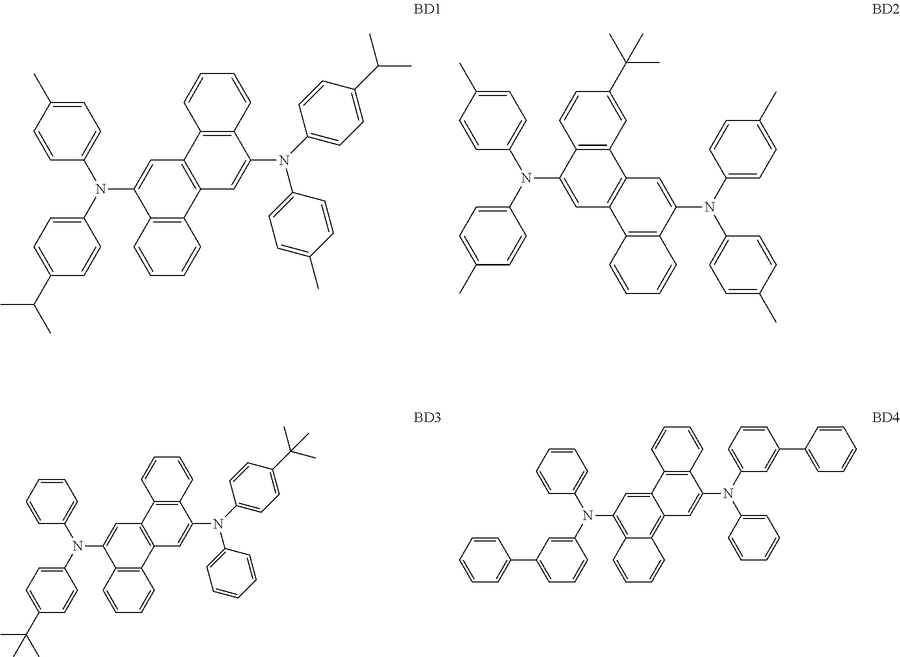 [SMILES: Cc1ccc(N(c2ccc(C(C)C)cc2)c2cc3c4ccccc4c(N(c4ccc(C)cc4)c4ccc(C(C)C)cc4)cc3c3ccccc23)cc1 ; Cc1ccc(N(c2ccc(C)cc2)c2cc3c4cc(C(C)(C)C)ccc4c(N(c4ccc(C)cc4)c4ccc(C)cc4)cc3c3ccccc23)cc1 ; CC(C)(C)c1ccc(N(c2ccccc2)c2cc3c4ccccc4c(N(c4ccccc4)c4ccc(C(C)(C)C)cc4)cc3c3ccccc23)cc1 ; c1ccc(-c2cccc(N(c3ccccc3)c3cc4c5ccccc5c(N(c5ccccc5)c5cccc(-c6ccccc6)c5)cc4c4ccccc34)c2)cc1]

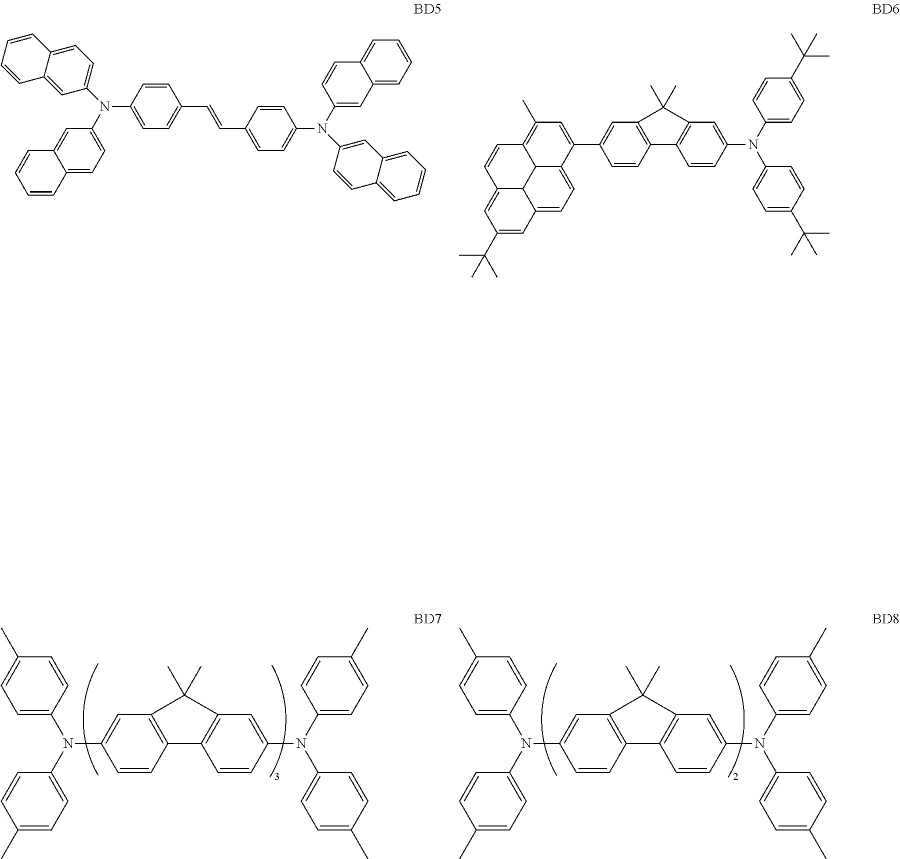

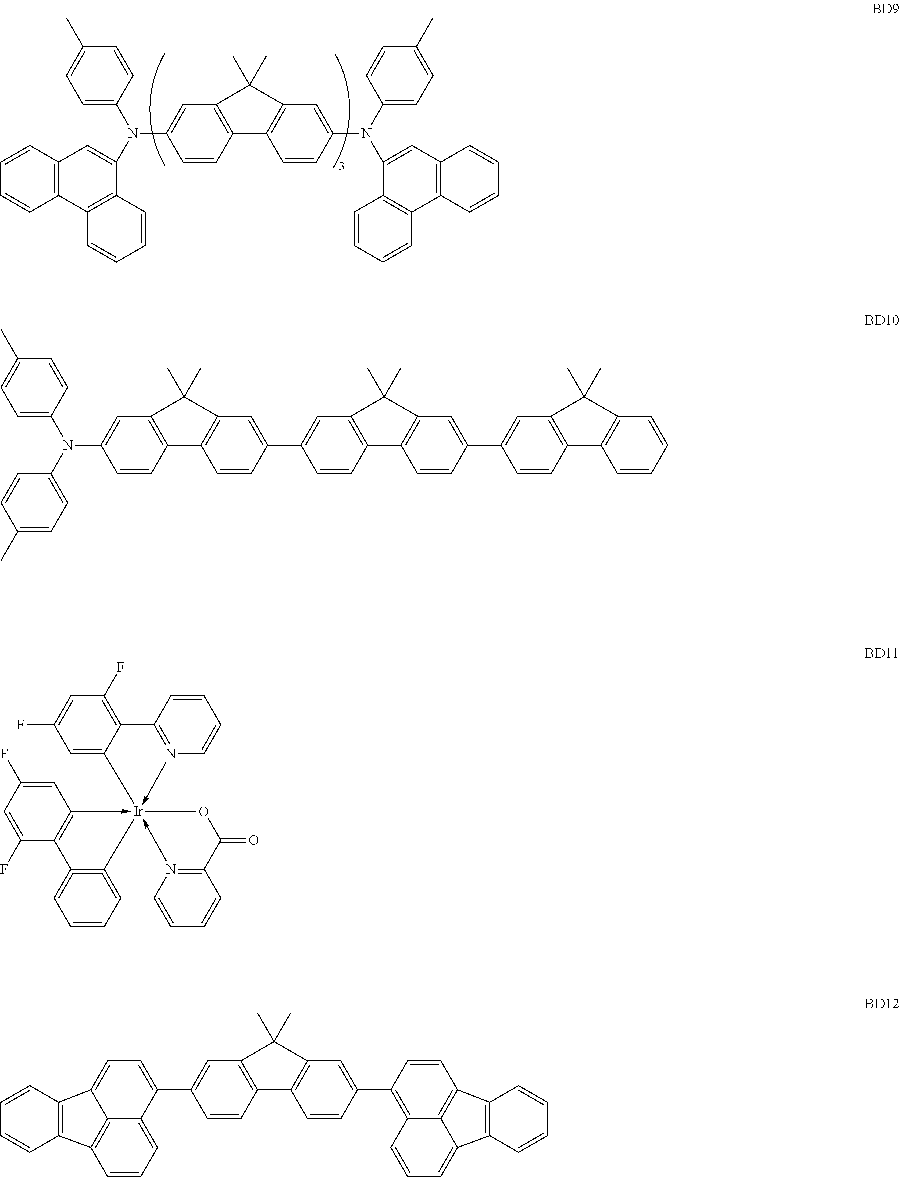

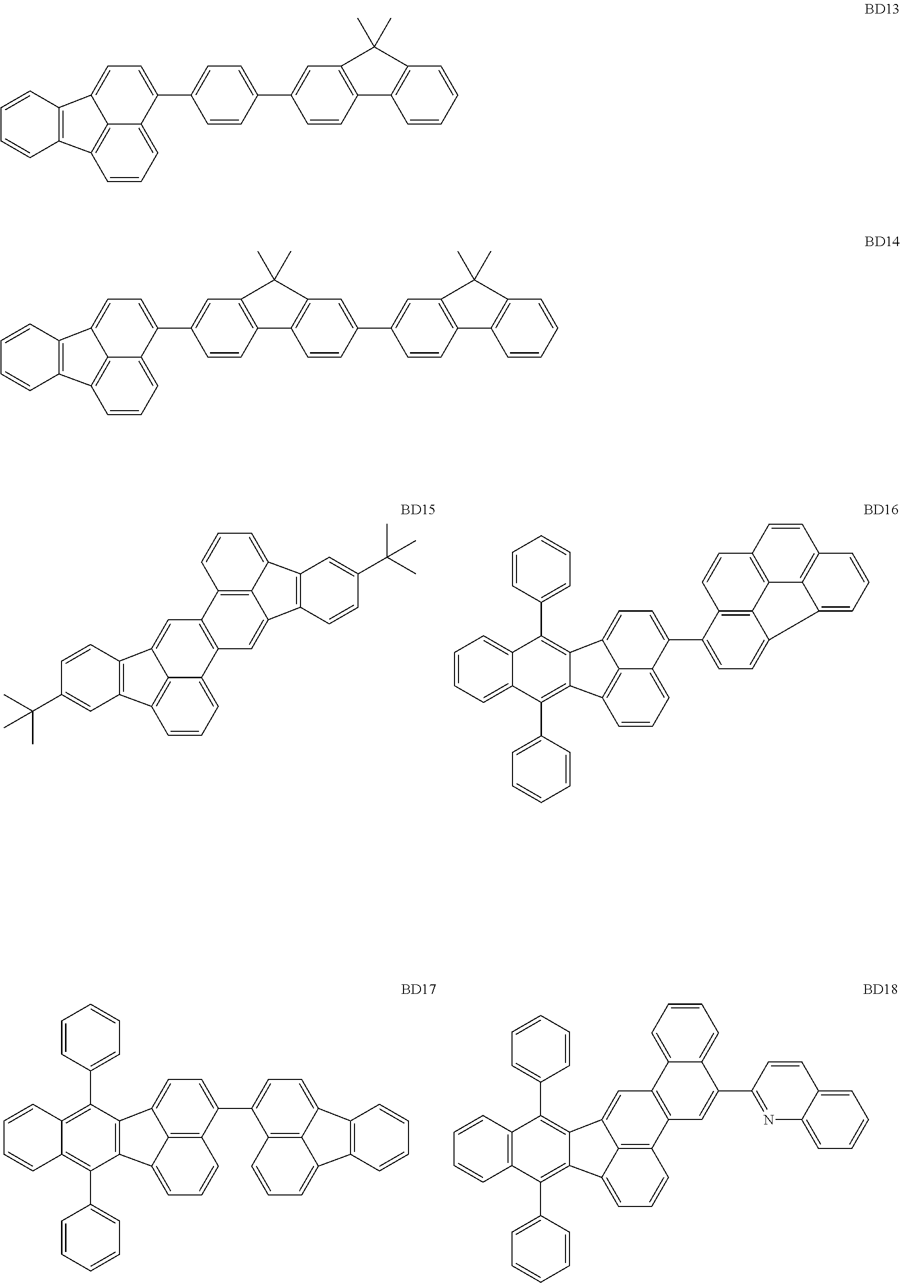

Compounds BD12 to BD18 having five-membered rings can efficiently trap electrons, and many of the blue luminescent layers 3B containing these luminescent dopants have an emission position at the boundary thereof on the electron transport layer side, as shown in FIGS. 2A and 3A. For the red organic EL element, the structures shown in FIGS. 2A and 2B are efficient, and the structure shown in FIG. 2A can be suitably applied to an embodiment.

### Second Charge Transport Layer

The second charge transport layer 4 is formed after the red luminescent layer 3R, the green luminescent layer 3G, the blue luminescent layer 3B, and the thickness adjustment layer 6 have been formed by vapor deposition through metal masks. The second charge transport layer 4 can be formed by, for example, vapor deposition, coating or transfer, as with the first charge transport layer 2. When the first electrode 1 is an anode, the second charge transport layer 4 is an electron transport layer. For the electron transport layer, a known phenanthroline derivative is used. The electron transport layer may be formed by depositing layers of an electron transport material and an electron injection material, and further a hole blocking material.

The electron injection material may be an alkali metal compound, an alkaline-earth metal compound, or an organic compound containing an alkali metal or alkaline-earth metal compound. In an embodiment of the present invention, the electron transport layer may include an electron injection layer and a hole blocking layer.

### Second Electrode

The second electrode 5 is formed on the second charge transport layer 4. The second electrode 5 is made of a metal as used in the first electrode 1. In order to enhance the electron injection of the second electrode 5 as a cathode, the second electrode may be made of a composite or multilayer film of an alkali metal, an alkaline-earth metal and their compound. In a top emission structure, the second electrode 5 is transparent and has such a thickness that light can be extracted.

As described above, metal masks are used only for forming four layers (the red, green and blue luminescent layers 3R, 3G and 3B and the thickness adjustment layer 6 of the red organic EL element). Thus, the first optical distance L₁ and the second optical distance L₂ of each of the red, green and blue organic EL elements can be set to one-fourth of the emission wavelength. Thus, the number of times the metal masks are used can be reduced, and in addition, a full color display apparatus exhibiting a high emission efficiency can be provided.

### Example

An example of the present invention will now be described. The materials and structures of the elements in the Example are not intended to limit the present invention.

TFTs, an organic planarizing layer, and Al/ITO multilayer electrodes formed in a pattern corresponding to the pixels were formed on a glass substrate. The Al/ITO electrodes were isolated by a polyimide element isolation film formed around each of the electrodes. The resulting substrate was subjected to UV/ozone cleaning. The first electrode 1 had an Al/ITO multilayer structure, and the ITO layer had a thickness of 10 nm.

After the substrate was placed in a vacuum deposition apparatus (manufactured by ULVAC), the apparatus was evacuated to 1.33×10⁻⁴ Pa (1×10⁻⁶ Torr). Then, compound HT13, a hole transport material, was vapor-deposited to a thickness of 17 nm over the surfaces of the first electrodes to form a first charge transport layer 2.

Then, a thickness adjustment layer 6 was formed by vapor-depositing compound HT4, a hole transport material, to a thickness of 45 nm on the portions of the first charge transport layer 2 that would act as red pixels, using a metal mask having a pattern corresponding to the pixels.

Subsequently, compound RH4 as a host material, compound RD9 (4% on a volume basis) as a luminescent dopant, and compound HT4 (15% on a volume basis) as an assistant dopant were co-deposited on the thickness adjustment layer 6 to a thickness of 25 nm through a metal mask having a patter corresponding to the pixels, thus forming a red luminescent layers 3R.

Green luminescent layers 3G were vapor-deposited on the portions of the first charge transport layer 2 that would act as green pixels, using a metal mask having a pattern corresponding to the pixels. More specifically, compound GH3 as a host material, compound GD16 (1.5% on a volume basis) as a luminescent dopant, and compound GD65 (60% on a volume basis) as an assistant dopant were co-deposited to a thickness of 35 nm. The energy bands of the green luminescent layer 3G were as follows, applying to relationship (I).

GH3:HOMO=5.72 eV,LUMO=2.78 eV

GD16:HOMO=5.75 eV,LUMO=3.25 eV

GD65:HOMO=5.58 eV,LUMO=2.97 eV

Then, blue luminescent layers 3B were formed by co-depositing compound BH14 as a host material and compound BH12 (0.5% on a volume basis) as a luminescent dopant to a thickness of 20 nm on the portions of the first charge transport layer 2 that would act as blue pixels, using a metal mask having a pattern corresponding to the pixels.

Then, a second charge transport layer 4 was formed by vapor-depositing a phenanthroline derivative expressed by the following formula to a thickness of 40 nm over the surfaces of the luminescent layers 3R, 3G and 3B.

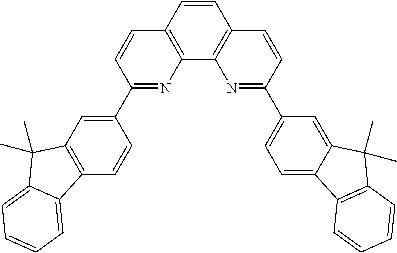

Subsequently, a second electrode 5 was formed by co-depositing cesium carbonate (3% on a volume basis) and Ag to a thickness of 6 nm on the second charge transport layer 4, and further vapor-depositing Ag to a thickness of 20 nm.

Then, the resulting substrate was placed in a glove box, which was purged with nitrogen and sealed with a glass cover with a desiccant.

The display apparatus prepared in the above-described process was evaluated. The wavelengths of light emitted from the display apparatus were λ_{R}=623 nm, λ_{G}=517 nm and λ_{B}=452 nm.

In the blue organic EL element, the reflection plane of the Al/ITO first electrode 1 is at the surface of the Al layer, and the thickness of the ITO layer is part of the first optical distance L_{1B}. Thus, the first optical distance L_{1B} of the blue organic EL element is the sum of the optical thicknesses of the ITO layer, the first charge transport layer 2 and the blue luminescent layer 3B. In the blue luminescent layer 3B, the luminescent dopant has a band structure that traps electrons, and the emission position 7B lies at the interface with the second charge transport layer 4. Therefore, the first optical distance L_{1B} is 10 nm×2.0+17 nm×1.8+20 nm×1.8=86.6 nm, wherein the refractive index of ITO is 2.0 and the refractive indices of the first charge transport layer 2 and the blue luminescent layer 3B are each 1.8.

The optical distance L_{2B} calculated from Equation (A) is 87.2 nm, wherein the phase shift φ calculated from the refractive index of the first electrode side and the absorption coefficient is −139°, and the emission wavelength λ_{B} is 452 nm. Thus, the first optical distance L_{1B} of the blue organic EL element prepared above is almost equal to one-fourth of the emission wavelength λ_{B}. The refractive index and the absorption coefficient are values obtained by measuring films of each material with a spectroscopic ellipsometer.

The table below shows the first and second optical distances L₁ and L₂ of the organic EL elements of each color prepared in the above Example, and their optical distances calculated from Equation (A). For the green organic EL element, since the assistant dopant content was optimized, the emission position, or the center of the light-emitting region, was assumed to be in the green luminescent layer 3G 7 nm inward from the interface between the luminescent layer 3G and the second charge transport layer 4.

TABLE

| | | R | G | B |
|---|---|---|---|---|
| First optical distance | Example | 132 | 101 | 87 |
| (nm) | Calculated from | 131 | 103 | 87 |
| | Equation (A) | | | |
| Second optical | Example | 117 | 85 | 72 |
| distance | Calculated from | 112 | 86 | 70 |
| (nm) | Equation (A) | | | |

### Comparative Example

For a display apparatus of the Comparative Example, the green organic EL element was also provided with a thickness adjustment layer, and its first and second optical distances L_{1G} and L_{2G} were set to be one-fourth of the green emission wavelength λ_{G}.

More specifically, the green luminescent layer 3G was formed to a thickness of 28 nm by co-depositing only the host material and the luminescent dopant without co-depositing an assistant dopant. Subsequently, a thickness adjustment layer was formed by depositing compound GH3 as a host material to a thickness of 7 nm on the green luminescent layer 3G. Other process steps were conducted in the same manner as in the Example, and thus a display apparatus was prepared.

In each organic EL elements of the display apparatuses of the Example and the Comparative Example, the first optical distance L₁ between the emission position of the luminescent layer and the reflection plane of the first electrode 1 and the second optical distance L₂ between the emission position and the reflection plane of the second electrode 4 are each set to be one-fourth of the emission wavelength of the corresponding organic EL element.

Evaluation results show that the display apparatuses of the Example and the Comparative Example exhibited a high emission efficiency and were thus satisfactory. While thickness adjustment layers, in the Comparative Example, were formed in the red and green organic EL elements through metal masks having a pattern corresponding to the pixels, a thickness adjustment layer, in the Example, was formed only in the red organic EL element. Accordingly, the cost of the metal mask can be reduced in the Example.

While the present invention has been described with reference to exemplary embodiments, it is to be understood that the present invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-238944 filed Oct. 31, 2011 and No. 2012-207713 filed Sep. 21, 2012, which are hereby incorporated by reference herein in their entirety.

What is claimed is:

1. A display apparatus comprising:
a red organic EL element that emits red light and includes a first electrode including a metal layer having a reflection plane, a first charge transport layer in contact with the first electrode, a red luminescent layer, a second charge transport layer, a second electrode in contact with the second charge transport layer and including a metal layer having a reflection plane, and a thickness adjustment layer between the first charge transport layer and the red luminescent layer or between the red luminescent layer and the second charge transport layer;
a green organic EL element that emits green light and includes a first electrode including a metal layer having a reflection plane, a first charge transport layer in contact with the first electrode, a green luminescent layer in contact with the first charge transport layer and containing a host material, a luminescent dopant, and an assistant dopant, a second charge transport layer in contact with the green luminescent layer, and a second electrode in contact with the second charge transport layer and including a metal layer having a reflection plane; and
a blue organic EL element that emits blue light and includes a first electrode including a metal layer having a reflection plane, a first charge transport layer in contact with the first electrode, a blue luminescent layer in contact with the first charge transport layer, a second charge transport layer in contact with the blue luminescent layer, and a second electrode in contact with the second charge transport layer and including a metal layer having a reflection plane,
wherein the first charge transport layer and second charge transport layer of each organic EL element are shared by all the organic EL elements and each have a constant thickness, and
wherein each respective organic EL element has a first optical distance L₁ between an emission position of the luminescent layer and the reflection plane of the first electrode and a second optical distance L₂ between the emission position of the luminescent layer and the reflection plane of the second electrode, and the first optical distance L₁ and the second optical distance L₂ satisfy the following relationships:
(λ/16)×(−1−(4φ₁/π))≦L₁≦(λ/16)×(1−(4φ₁/π)); and
(λ/16)×(−1−(4φ₂/π))≦L₂≦(λ/16)×(1−(4φ₂/π),
wherein λ represents the emission wavelength of the respective organic EL element, φ₁ represents phase shift of light reflecting from the first electrode of the respective organic EL element, and φ₂ represents phase shift of light reflecting from the second electrode of the respective organic EL element.

2. The display apparatus according to claim 1,
wherein the emission position of the blue luminescent layer lies at the interface between the blue luminescent layer and the second charge transport layer of the blue organic EL element, the first optical distance of the blue organic EL element has been set by controlling the thicknesses of the first charge transport layer and the luminescent layer, and the second optical distance of the blue organic EL element has been set by controlling the thickness of the second charge transport layer,
wherein the first and second optical distances of the green organic EL element each have been set by controlling the thicknesses of the first charge transport layer, the green luminescent layer, and the second charge transport layer, and the assistant dopant content in the green luminescent layer, and
wherein the thickness adjustment layer is disposed between the red luminescent layer and the first charge transport layer of the red organic EL element, the first optical distance of the red organic EL element has been set by controlling the thicknesses of the first charge transport layer and the thickness adjustment layer, and the second optical distance has been set by controlling the thicknesses of the second charge transport layer and the red luminescent layer.

3. The display apparatus according to claim 2, wherein the red luminescent layer contains a host material, a luminescent dopant and an assistant dopant, and the thickness adjustment layer is made of the same material as the assistant dopant of the red luminescent layer.

4. The display apparatus according to claim 1, wherein the green organic EL element satisfies relationship (I):
LUMO_{Gh}<LUMO_{Ga}<LUMO_{Ge}<HOMO_{Ga}<HOMO_{Gh}<HOMO_{Ge} (I)
wherein LUMO_{Gh}, LUMO_{Ge} and LUMO_{Ga} represent absolute values of energy levels of the lowest unoccupied molecular orbitals of the host material, luminescent dopant and assistant dopant of the green luminescent layer, respectively, and HOMO_{Gh}, HOMO_{Ge} and HOMO_{Ga} represent absolute values of energy levels of the highest occupied molecular orbitals of the host material, luminescent dopant and assistant dopant of the green luminescent layer, respectively.

5. The display apparatus according to claim 1, wherein the first optical distance L₁ and second optical distance L₂ of each organic EL element satisfy the following relationships:
3λ/16≦L₁≦5λ/16; and
3λ/16L₂≦5λ/16.
